(19) United States
(12) Patent Application Publication
(10) Pub. No.: US 2025/0006569 A1
(43) Pub. Date: Jan. 2, 2025

(54) METHODS AND APPARATUS FOR PACKAGE SUBSTRATES WITH STACKS OF GLASS LAYERS HAVING DIFFERENT COEFFICIENTS OF THERMAL EXPANSION

(71) Applicant: Intel Corporation, Santa Clara, CA (US)

(72) Inventors: Gang Duan, Chandler, AZ (US); Minglu Liu, Chandler, AZ (US); Srinivas Venkata Ramanuja Pietambaram, Chandler, AZ (US)

(73) Assignee: Intel Corporation, Santa Clara, CA (US)

(21) Appl. No.: 18/883,759

(22) Filed: Sep. 12, 2024

(51) Int. Cl. H01L 23/15; H01L 23/24; H01L 23/367; H01L 23/538

(52) U.S. Cl. CPC H01L 23/15; H01L 23/24; H01L 23/3675; H01L 23/5385

(57) ABSTRACT

Systems, apparatus, articles of manufacture, and methods for package substrates with stacks of glass layers having different coefficients of thermal expansion are disclosed. An example substrate for an integrated circuit package includes: a first glass layer having a first coefficient of thermal expansion (CTE); and a second glass layer having a second CTE, the second CTE different from the first CTE.

### BACKGROUND

Integrated circuit (IC) chips and/or semiconductor dies are routinely connected to larger circuit boards such as motherboards and other types of printed circuit boards (PCBs) via a package substrate. As IC chips and/or dies reduce in size and interconnect densities increase, alternatives to traditional substrate layers are being developed to provide stable transmission of high-frequency data signals between different circuitry and/or increased power delivery. One option being pursued is the implementation of package substrates with glass cores. Generally, glass core implementations offer several advantages compared to implementations with conventional epoxy cores, including a higher plated through-hole (PTH) density, lower signal losses, and lower total thickness variation.

### BRIEF DESCRIPTION OF THE DRAWINGS

FIG. 1 illustrates an example integrated circuit (IC) package constructed in accordance with teachings disclosed herein.

FIG. 2 illustrates an example substrate core that may be used to implement the example substrate core of FIG. 1.

FIGS. 3-11 illustrate different stages in an example fabrication process to manufacture the example substrate core of FIG. 2.

FIG. 12 illustrates another example substrate core that may be used to implement the example substrate core of FIG. 1.

FIG. 13 illustrates another example substrate core that may be used to implement the example substrate core of FIG. 1.

FIGS. 14-23 illustrate different stages in another example fabrication process to manufacture the example substrate core of FIG. 13.

FIG. 24 illustrates an example package substrate that may be used to implement the example package substrate of FIG. 1.

FIGS. 25-35 illustrate different stages in an example fabrication process to manufacture the example substrate core of FIG. 24.

FIG. 36 illustrates another example package substrate that may be used to implement the example package substrate of FIG. 1.

FIG. 37 illustrates another example package substrate that may be used to implement the example package substrate of FIG. 1.

FIGS. 38-48 illustrate different stages in an example fabrication process to manufacture the example substrate core of FIG. 37.

FIG. 49 is a flowchart representative of an example method that may be performed to fabricate any one of the example package substrates and/or associated example substrate cores of FIGS. 1-48.

FIG. 50 is a top view of a wafer including dies that may be included in an IC package constructed in accordance with teachings disclosed herein.

FIG. 51 is a cross-sectional side view of an IC device that may be included in an IC package constructed in accordance with teachings disclosed herein.

FIG. 52 is a cross-sectional side view of an IC device assembly that may include an IC package constructed in accordance with teachings disclosed herein.

FIG. 53 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

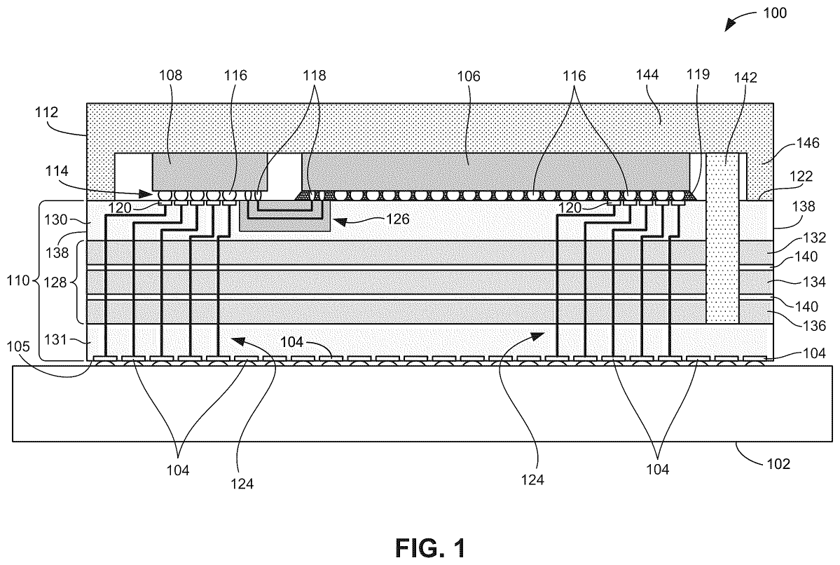

FIG. 1 illustrates an example integrated circuit (IC) package 100 constructed in accordance with teachings disclosed herein. In the illustrated example, the IC package 100 is electrically coupled to a circuit board 102 via an array of contacts 104 on a mounting surface 105 (e.g., a bottom, external surface) of the package. In the illustrated example, the contacts 104 are represented as pads or lands. However, in some examples, the IC package 100 may include balls, pins, and/or any other type of contact, in addition to or instead of the pads or lands shown to enable the electrical coupling of the IC package 100 to the circuit board 102. In this example, the IC package 100 includes two semiconductor (e.g., silicon) dies 106, 108 (sometimes also referred to as chips or chiplets) that are mounted to a package substrate 110 and enclosed by a package lid 112 (e.g., a mold compound, an integrated heat spreader (IHS)). Thus, the package substrate 110 is an example means for supporting a semiconductor die. While the example IC package 100 of FIG. 1 includes two dies 106, 108, in other examples, the IC package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example, each of the dies 106, 108 is electrically and mechanically coupled to the package substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the package substrate 110 (e.g., the interconnects 114) are sometimes referred to as first level interconnects. By contrast, the electrical connections between the IC package 100 and the circuit board 102 (e.g., the contacts 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 (e.g., the upper, internal surface, the top surface, etc.) of the package substrate 110. The contact pads 120 on the inner surface 122 of the package substrate 110 are electrically coupled to the contacts 104 on the mounting surface 105 (e.g., the bottom, external surface) of the package substrate 110 (e.g., a surface opposite the inner surface 122) via internal interconnects 124 within the package substrate 110. As a result, there is a continuous electrical signal path between the core bumps 116 of the dies 106, 108 and the contacts 104 mounted to the circuit board 102 that pass through the contact pads 120 and the interconnects 124 provided therebetween.

As used herein, the bridge bumps 118 are bumps on the dies 106, 108 through which electrical signals pass between different ones of the dies 106, 108 within the IC package 100. Thus, as shown in the illustrated example, the bridge bumps 118 of the first die 106 are electrically coupled to the bridge bumps 118 of the second die 108 via an interconnect bridge 126 (e.g., a silicon-based interconnect bridge, an interconnect die, an embedded interconnect bridge (EMIB)) embedded in the package substrate 110. As represented in FIG. 1, core bumps 116 are typically larger than bridge bumps 118. In some examples, interconnect bridge 126 and the associated bridge bumps 118 are omitted.

In some examples, an underfill material 119 is disposed between the dies 106, 108 and the package substrate 110 around and/or between the first level interconnects 114 (e.g., around and/or between the core bumps 116 and/or the bridge bumps 118). In the illustrated example, only the first die 106 is associated with the underfill material 119. However, in other examples, both dies 106, 108 are associated with the underfill material 119. In other examples, the underfill material 119 is omitted. In some examples, the mold compound used for the package lid 112 is used as an underfill material that surrounds the first level interconnects 114.

In some examples, the IC package 100 includes additional passive components, such as surface-mount resistors, capacitors, and/or inductors disposed on the mounting surface 105 of the package substrate 110 and/or the inner surface 122 of the package substrate 110.

In FIG. 1, the substrate 110 of the example IC package 100 includes a substrate core 128 (e.g., a main core, an overall core) between two separate build-up layers or regions 130, 131 (e.g., redistribution layers or regions). As shown in the illustrated example, the substrate core 128 includes multiple distinct glass cores (e.g., multiple glass layers, multiple glass core layers, etc.), namely an example top glass core 132 (e.g., a first glass core), an example middle glass core 134 (e.g., a second glass core), and an example bottom glass core 136 (e.g., a third glass core). In the illustrated example of FIG. 1, the glass cores 132, 134, 136 (e.g., sub-cores, glass substrates, glass layers, glass sheets) are stacked on top of one another.

In some examples, the cores 132, 134, 136 include at least one of: aluminosilicate, borosilicate, alumino-borosilicate, silica, and/or fused silica. In some examples, the cores 132, 134, 136 include one or more additives including: aluminum oxide (Al₂O₃), boron trioxide (B₂O₃), magnesia oxide (MgO), calcium oxide (CaO), stoichiometric silicon oxide (SrO), barium oxide (BaO), stannic oxide (SnO₂), nickel alloy (Na₂O), potassium oxide (K₂O), phosphorus trioxide (P₂O₃), zirconium dioxide (ZrO₂), lithium oxide (Li₂O), titanium (Ti), and/or zinc (Zn). In some examples, the cores 132, 134, 136 include silicon and oxygen. In some examples, the cores 132, 134, 136 include silicon, oxygen and/or one or more of aluminum, boron, magnesium, calcium, barium, tin, sodium, potassium, strontium, phosphorus, zirconium, lithium, titanium, and/or zinc. In some examples, the cores 132, 134, 136 include at least 23 percent silicon by weight and at least 26 percent oxygen by weight. In some examples, the glass cores 132, 134, 136 are individual layers of glass including silicon, oxygen, and aluminum. In some examples, the cores 132, 134, 136 include at least 23 percent silicon by weight, at least 26 percent oxygen by weight, and at least 5 percent aluminum by weight.

In some examples, the cores 132, 134, 136 are amorphous solid glass layers. In some examples, the cores 132, 134, 136 are layers of glass that do not include an organic adhesive or an organic material. In some examples, the cores 132, 134, 136 are solid layers of glass having a rectangular shape in plan view. In some examples, the cores 132, 134, 136, as glass substrates, include at least one glass layer and do not include epoxy and do not include glass fibers (e.g., do not include an epoxy-based prepreg layer with glass cloth). In some examples, the cores 132, 134, 136 correspond to single pieces of glass that extend the full height/thickness of each corresponding core.

In some examples, the cores 132, 134, 136 have a rectangular shape that is substantially coextensive, in plan view, with the layers above and/or below the core. In some examples, the cores 132, 134, 136 have a thickness in a range of about 25 micrometers (μm) to about 400 μm (with the overall thickness of the substrate core 128 ranging from about 50 μm to about 1.4 millimeters (mm)). In some examples, the cores 132, 134, 136 can have dimensions of about 10 mm on a side to about 250 mm on a side (e.g., 10 mm by 10 mm to 250 mm by 250 mm). In some examples, the cores 132, 134, 136 correspond to rectangular prism volumes with sections (e.g., vias) removed and filled with other materials (e.g., metal).

The build-up regions 130, 131 are represented in FIG. 1 as masses/blocks with the internal interconnects 124 extending in straight lines through the build-up regions 130, 131 (and the glass cores 132, 134, 136). However, FIG. 1 has been simplified for the sake of clarity and purposes of explanation. In practice, the interconnects are not necessarily straight. More particularly, in some examples, the build-up regions 130, 131 are defined by alternating layers of dielectric material and layers of conductive material (e.g., a metal such as copper). The conductive (metal) layers serve as the basis for the internal interconnects 124 represented, in a simplified form, by straight lines as shown in FIG. 1. In some examples, the metal layers are patterned to define electrical routing or conductive traces that are electrically coupled between different metal layers by conductive (e.g., metal) vias extending through intervening dielectric layers. Further, the electrical routing or traces on either side of the substrate core 128 may be electrically coupled by through-glass vias (TGVs) (e.g., copper plated vias) extending through the glass cores 132, 134, 136.

In some examples, one or both of the build-up regions 130, 131 may be omitted. That is, in some examples, the stack of glass cores 132, 134, 136 defines most (e.g., all or substantially all) of the thickness of the package substrate 110 (e.g., all except for outer solder resist layers, all except for a reduced set of metallization layers in the build-up regions 130, 131, etc.). In some such examples, the stack of glass cores 132, 134, 136 includes more than three glass layers and the redistribution of electrical paths defined by the interconnects 124 is achieved by traces or routing running parallel to and between adjacent ones of the glass layers.

Among other things, glass cores are advantageous over epoxy-based cores because glass is stiffer and, therefore, provides for greater mechanical support or strength for the package substrate. Thus, the substrate core 128 and, more particularly, the individual glass cores 132, 134, 136 are example means for strengthening the package substrate. In addition to mechanical benefits, glass cores also provide other advantages including a higher plated through-hole (PTH) density, lower signal losses, and a lower total thickness variation. Further, glass can be fabricated with much flatter surfaces than is possible with epoxy-based materials. As a result, glass can serve as the basis for dielectric layers and/or metallization layers in the build-up regions being developed much thinner and with greater control. In some examples, the higher PTH density available with glass cores and the greater control in developing layers of materials on the relatively flat surfaces of glass cores can enable build-up regions (e.g., redistribution layers or regions) with finer line spacing. For instance, some known epoxy-based package substrates include dielectric layers having a thickness of approximately 25 μm. By contrast, some examples disclosed herein can include dielectric layers having a thickness of less than or equal to approximately 10 μm, less than or equal to approximately 5 μm, less than or equal to approximately 1 μm, etc.

Although the above advantages may be realized in disclosed examples, glass cores also present challenges due to the fragile (e.g., brittle) nature of glass and the possibility of defects that can develop into cracks that propagate through the glass. A common type of failure of known glass cores is referred to as a seware failure. Seware failures result in the separation of a glass core along a crack that propagates from an edge of the glass core along its length and width between the main outer surfaces (e.g., upper and lower surfaces, front and back surfaces) of the glass core. That is, seware failures are characterized by a glass core being split into two separate sheets of glass along a line extending generally parallel to the main plane of the glass core.

Factors that contribute to seware failures include defects on the edges of glass cores resulting from singulation and the internal stress induced by a mismatch in coefficient of thermal expansion (CTE) between the glass core (e.g., a CTE of around 3 ppm/° C. to 10 ppm/° C.) and the material in the build-up regions (e.g., a CTE of around 39 ppm/° C. for the organic dielectric layers, a CTE of around 17 ppm/° C. for the copper, and a CTE around 2.6 ppm/° C. for silicon) during thermal cycles of the package substrate 110 (either during the fabrication process or during use thereafter). More particularly, package substrates, such as the package substrate 110 of FIG. 1, are often fabricated on a large panel that is subsequently singulated or cut into individual units with a saw. Thus, in the illustrated example of FIG. 1, the package substrate 110, including the substrate core 128 (and the associated sub-cores 132, 134, 136) and the build-up regions 130, 131, include opposing edges 138 that are created by the cut of a saw. Such sawing can result in defects developing on the edges of glass cores (e.g., the edges 138 of the glass cores 132, 134, 136 in FIG. 1) that can give rise to cracks that propagate laterally across the middle of the glass core to split the glass core into two main pieces. The development and propagation of cracks in this manner is exacerbated by stress induced by fluctuations in temperature and the difference in CTE of the build-up regions relative to the CTE of the glass core. Generally, the material in the build-up regions 130, 131 has a higher CTE than glass. As a result, the material in the build-up regions 130, 131 expands and contracts more than a glass core in response to thermal fluctuations, thereby causing internal stress within the glass core that can promote crack propagation.

Examples disclosed herein reduce (e.g., minimize) concerns for seware failures by implementing the substrate core 128 of the substrate with multiple distinct (e.g., disaggregated) glass cores (e.g., the glass cores 132, 134, 136) stacked on top of one another as shown in FIG. 1. More particularly, in examples disclosed herein, the different stacked cores are implemented by different materials (or different compositions of the same materials) associated with different material properties (e.g., different CTEs). That is, in some examples, the different CTEs of different glass cores 132, 134, 136 can be tuned tailoring (e.g., modifying, changing, etc.) the relative proportions of Al₂O₃, B₂O₃, Li₂O, Na₂O, K₂O, Sb₂O₃, and/or other additives in each of the layers and/or via processing variations (e.g., lamination cladding, thermal treatment, etc.). In some examples, the glass cores that are closer to the build-up regions 130, 131 are fabricated with a CTE that is closer to the CTE of the build-up regions 130, 131 than the CTE of the glass cores farther away from the build-up regions 130, 131 (e.g., closer to the middle of the stack of glass cores). In this manner, the substrate core 128 is defined by a gradation of CTEs or incremental changes in CTE (e.g., between adjacent ones of the glass core 132, 134, 136 in the stack) that provide a transition between the different layers in the package substrate 110 to reduce stress at any given location.

For instance, in some examples, the middle glass core 134 has a lower CTE than the top glass core 132 and a lower CTE than the bottom glass core 136. In some examples, the CTE of the top glass core 132 and the bottom glass core 136 are the same. Thus, in some examples, the different CTEs of the glass cores 132, 134, 136 are symmetrical across the overall thickness of the substrate core 128. That is, the arrangement or ordering of the stack of glass cores 132, 134, 136 and their associated CTEs define a symmetric sequence of CTEs (e.g., a symmetrical CTE gradient) from a lowermost glass core (e.g., the third glass core 136) to an uppermost glass core (e.g., the first glass core 132). In some such examples, the lowest CTE value in the symmetrical CTE gradient is closer to the middle of the stack of multiple glass cores than a highest CTE value in the symmetrical CTE gradient (which are closer the upper and lower sides of the stack). In other examples, the different CTEs may not be symmetrical. For instance, in some examples, the top glass core 132 (e.g., the glass core closest to the dies 106, 108) has the highest CTE in the stack and the bottom glass core 136 (e.g., the glass core farthest from the dies 106, 108) has the lowest CTE with the central glass core 134 having a CTE between the other two. In other examples, the top glass core 132 (e.g., the glass core closest to the dies 106, 108) has the lowest CTE in the stack with the bottom glass core 136 having the highest CTE in the stack. Any other suitable arrangement of differing CTE values across any suitable number of stacked glass cores may additional or alternatively be implemented to achieve any suitable CTE gradient across the overall substrate core 128.

In addition to implementing multiple glass cores (e.g., the glass cores 132, 134, 136) with different CTEs to reduce stress, in some examples, as already noted above, one or both of the build-up regions 130, 131 is omitted or significantly reduced in thickness (e.g., reduced in the number of metallization layers included therein and/or implemented with much thinner layers). As a result, there is less stress produced on the glass cores 132, 134, 136 from the CTE mismatch between the glass and the build-up regions 130, 131.

Further, in some examples, a buffer material 140 (e.g., buffer layer, adhesive material/layer) is disposed between adjacent ones of the glass cores 132, 134, 136 to hold the glass cores together. In some such examples, the buffer material 140 has a relatively low modulus of elasticity to absorb stress resulting from thermal fluctuations and the different CTEs of the different glass cores 132, 134, 136, thereby further reducing stress internal to the substrate core 128. In some examples, the buffer material 140 is an organic dielectric material (e.g., polyimide, parylene, etc.). In some examples, the buffer material 140 is an inorganic dielectric material (e.g., silicon oxide (SiOₓ), silicon nitride (SiNₓ)). In some examples, the buffer material 140 includes a carbon doped oxide (CDO). In some examples, the buffer material 140 includes the same or similar dielectric material used in the build-up regions 130, 131. In some examples, the layers of the buffer material 140 include conductive material that facilitates the redistribution of electrical paths between the glass cores 132, 134, 136. Thus, the materials between the glass cores are also referred to herein as redistribution material. Redistribution material may include one or more redistribution layers in the package substrate 110. Likewise, in such examples, the stack of glass cores 132, 134, 136 is sometimes referred to herein as a redistribution region or redistribution layer. In some examples, one or more of the layers of the buffer material 140 may be omitted such that different ones of the glass cores 132, 134, 136 are directly abutting. In some such examples, the stack of glass cores 132, 134, 136 may still function as a redistribution region or layer based on traces or routing being located in etched trenches along the planes of one or more of the glass cores 132, 134, 136.

The higher PTH density and finer line spacing of some examples is associated with higher IO density, which is associated with greater amounts of heat that need to be dissipated. In many known IC packages, heat is dissipated from the backside of the semiconductor dies (e.g., the side facing away from a package substrate) through an integrated head spreader IHS (e.g., similar to the package lid 112). In some examples disclosed herein, the IC package 100 includes one or more metal slug(s) 142 positioned within and/or extending through one or more of the glass cores 132, 134, 136. In such examples, the metal slug(s) 142 extend up to and/or are otherwise thermally coupled to the package lid 112 and/or other exterior portion of the IC package 100. As a result, the slug(s) 142 provide a thermally conductive path from an interior of the stack of multiple glass cores 132, 134, 136 (e.g., adjacent the front side of the semiconductor dies 106, 108) to an exterior surface of the IC package 100 to facilitate the dissipation of heat. In some examples, the metal slug(s) 142 are composed of the same metal used in the interconnects 124 (e.g., copper). The metal slug 142 of the illustrated example is thermally coupled to an upper wall 144 of the lid 112. In other examples, the metal slug 142 is thermally coupled to a lateral wall 146 of the lid 112. In some examples, the metal slug 142 is coupled to both the upper wall 144 and the lateral wall 146. In some examples, the metal slug 142 is omitted.

Although three different glass cores (e.g., the glass cores 132, 134, 136) are shown in the example substrate core 128 of FIG. 1, any other suitable number of glass cores may be implemented with corresponding CTEs to define a particular CTE gradient across the overall thickness of the substrate core 128. Thus, in some examples, only two glass cores, each with a different CTE, are employed. In other examples, more than three glass cores are employed. In some such examples, each glass core is different than every other glass core in the stack of cores. In other examples, two or more of the glass cores may have the same CTE (e.g., made from the same materials with the same composition) with at least one glass core having a different CTE than the others.

In the illustrated example of FIG. 1, each of the glass cores 132, 134, 136 is shown as having the same thickness (e.g., an approximately equal thickness). However, in some examples, the thickness of the glass cores 132, 134, 136 may differ from one another. For instance, in some examples, the middle glass core 134 is thicker than the top glass core 132 and thicker than the bottom glass core 136. In other examples, the middle glass core 134 is thinner than the top glass core 132 and thinner than the bottom glass core 136. Any suitable thickness(es) for the glass cores can be implemented to achieve a suitable CTE gradient that reduces stress to mitigate against to seware failures while also providing sufficient rigidity for the package substrate.

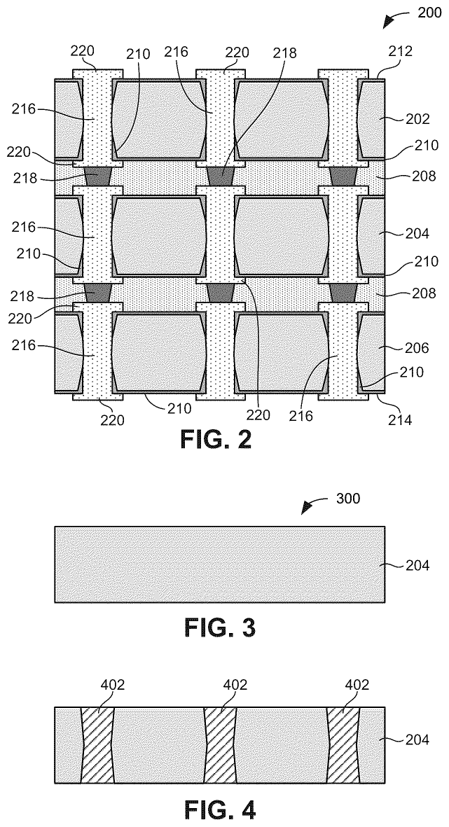

FIG. 2 illustrates an example substrate core 200 that may be used to implement the example substrate core 128 of FIG. 1. Similar to FIG. 1, the substrate core 200 of FIG. 2 includes a first glass core 202 (e.g., a top glass core, an uppermost glass core), a second glass core 204 (e.g., a middle glass core), and a third glass core 206 (e.g., a bottom glass core, a lowermost glass core) that are stacked on top of one another. In other examples, a different number of glass cores can be included in the stack. In this example, the different glass cores 202, 204, 206 correspond to the glass cores 132, 134, 136 of FIG. 1. Thus, the glass cores 202, 204, 206 include different CTEs as described above. For instance, in some examples, the second glass core 204 (e.g., the middle glass core) has a lower CTE than either the first glass core 202 or the third glass core 206. In this example, each of the glass cores 202, 204, 206 have approximately the same thickness. In some examples, the thickness is approximately 350 μm. In other examples, the thickness can be greater or less than 350 μm. Further, in some examples, different ones of the glass cores 202, 204, 206 can have different thicknesses. Additionally, while three glass cores are shown, in some examples, any other suitable number of glass cores (e.g., 2, 4, 5, 6, 7, etc.) may be employed. In such examples, the stack of glass cores can define any suitable CTE gradient based on differences in the CTE for each glass core in the stack. In some examples, the CTE gradient is symmetrical across the overall thickness of the substrate core 200. In other examples, the CTE gradient is not symmetrical.

In the illustrated example, the different glass cores 202, 204, 206 are separated by intervening layers of dielectric material 208 (e.g., adhesive material, adhesive resin). In some examples, the dielectric material 208 includes an organic epoxy-based dielectric. However, any other suitable dielectric may additionally or alternatively be used.

In some examples, a liner 210 is located between the dielectric material 208 and the interfacing surfaces of the glass cores 202, 204, 206. Further, in this example, the liner 109 also covers the outermost surfaces of the outermost glass cores (e.g., the first and third glass cores 202, 206). Thus, in this example, the liner 210 defines first and second outer surfaces 212, 214 of the overall substrate core 200. However, in some examples, the outermost layers of the liner 210 are omitted. In such examples, the outer surfaces of the first and third glass cores 202, 206 define the first and second outer surfaces 212, 214 of the overall substrate core 200.

In some examples, the liner 210 includes the same or similar material as the dielectric material 208. Thus, in some such examples, the liner 210 has a relatively low modulus of elasticity to help absorb stress resulting from thermal fluctuations and the different CTEs of the different glass cores 202, 204, 206. In some examples, the liner 210 is an organic dielectric material (e.g., polyimide, parylene, etc.). In some examples, the liner 210 is an inorganic dielectric material (e.g., silicon oxide (SiOₓ), silicon nitride (SiNₓ)). In some examples, the liner 210 includes a carbon doped oxide (CDO).

In the illustrated example of FIG. 2, the glass cores 202, 204, 206 include through glass vias (TGVs) 216 that are electrically coupled by additional conductive material 218 extending through the intervening layers of the dielectric material 208. In some examples, the TGVs 216 are plated with the same material as used in the additional conductive material 218 (e.g., copper, aluminum, nickel, tin, etc.). In some examples, at least some of the additional conductive material 218 contains a different material than the TGVs 216. Further, as shown in the illustrated example, conductive pads 220 are positioned at either end of the respective TGVs 216 (e.g., adjacent the opposing surfaces of the corresponding glass core 202, 204, 206). In some examples, the conductive pads 220 are integral extensions of the TGVs 216 within the glass cores 202, 204, 206. Thus, as shown in the illustrated examples, the conductive pads 220 electrically couple the TGVs 216 and the additional conductive material 218. In this example, the outermost conductive pads 220 (e.g., along the first and second outer surfaces 212, 214) define opposite ends of interconnects (e.g., portions of the interconnects 124 of FIG. 1) extending through the full thickness of the substrate core 200. Although three TGVs 216 are shown in each glass core 202, 204, 206, there may be any suitable number of TGVs 216 and they may be positioned at any suitable location(s) across the plane of the of glass cores 202, 204, 206.

In some examples, as shown in FIG. 2, the liner 210 lines the inner walls of the openings through the glass cores 202, 204, 206 that define the TGVs 216. That is, in some examples, the liner 210 surrounds the TGVs 216 to separate the glass cores 202, 204, 206 from the TGVs 216. In some examples, the liner 210 extends the full length of the TGVs 216 (e.g., the full thickness of a corresponding glass core 202, 204, 206) so that there is no contact between the glass cores 202, 204, 206 and the TGVs 216. In other examples, the liner 210 extends partially into the glass cores 202, 204, 206, but less than the full length of the TGC (e.g., less than the full thickness of the glass core 202, 204, 206). More particularly, as shown in the illustrated example of FIG. 2, the liner 210 is within the glass cores 202, 204, 206 adjacent the opposing ends of the TGVs 216 and spaced apart from a central portion of the TGVs 216. In this manner, the liner 210 is positioned at a known stress-concentration locations (e.g., the points on the glass cores 202, 204, 206 adjacent to where the TGVs 216 intersect the conductive pads (sometimes referred to as the triple-point)) to act as a buffer that reduces stress at those locations. In some examples, the liner 210 is omitted within the openings of the glass cores 202, 204, 206 defining the TGVs 216. In some examples, the liner 210 is omitted everywhere in the substrate core 200.

FIGS. 3-11 illustrate different stages in an example fabrication process to manufacture the example substrate core 200 of FIG. 2. FIG. 3 represents a glass panel 300 corresponding to the initial state of any one of the glass cores 202, 204, 206. For purposes of explanation, the glass panel 300 is shown and described as corresponding to the second glass core 204 (e.g., the middle glass core in the substrate core 200 of FIG. 2). In some examples, the glass panel 300 is fabricated to a thickness corresponding to the final thickness of the glass core 204. However, in some examples, the glass panel 300 is initially slightly larger than the final thickness of the glass core 204 to enable some amount of the glass to be removed during subsequent polishing or planarization processes as discussed further below.

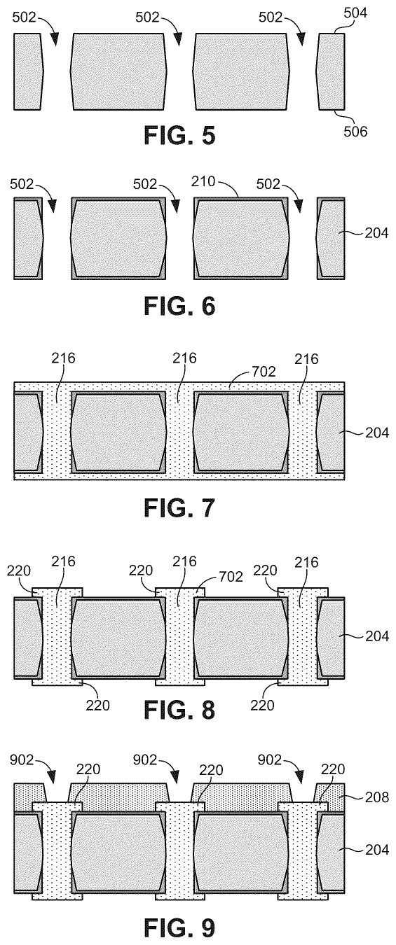

FIG. 4 represents the stage of fabrication following exposure of the glass core 204 of FIG. 3 to a laser as part of a laser induced deep etching (LIDE) process. The laser is concentrated on defined regions 402 of the glass core 204 to modify the optical and chemical properties of the glass core 204 at those regions 402. FIG. 5 represents the stage of fabrication following a chemical etch process to remove the material in the modified regions 402 of the glass core 204 shown in FIG. 4 to define openings 502 (e.g., holes) for the TGVs 216 shown in FIG. 2. In this example, the openings 502 have a cross-sectional profile generally corresponding to an hourglass shape with the width (e.g., diameter) of the openings 502 being narrower near a midpoint of the openings between opposing first and second surfaces 504, 506 of the glass core 204. In other examples, one or more of the openings 502 may have a different cross-sectional shape. For instance, in some examples, one or more of the openings 502 may have a generally conical or tapered shape with the width (e.g., diameter) being smallest at one of the two surfaces 504, 506 of the glass core 204 and the width (e.g., diameter) being largest at the opposite surface 504, 506. In other examples, the width (e.g., diameter) of one or more of the openings 502 is approximately consistent along a full length of the openings 502 between the opposing surfaces 506, 508 of the glass core 204.

FIG. 6 represents the stage of fabrication following the coating of the glass core 204 of FIG. 5 with the liner 210 of FIG. 2. In some examples, the liner 210 is deposited using a non-directional thin film deposition technique (e.g., chemical vapor deposition (CVD, atomic layer deposition (ALD), etc.). In such examples, all exposed surfaces of the glass core 204 will be coated. In other examples, a directional thin film deposition technique (e.g., physical vapor deposition (PVD), spray coating, etc.) may be employed to deposit the liner 210 to either side (e.g., each outer surface 504, 506) and only partially coating the inner walls of the openings 502, as shown in the illustrated example.

FIG. 7 represents the stage of fabrication following the depositing (e.g., plating) of a conductive material 702 (e.g., copper, aluminum, nickel, tin, etc.) within the openings 502 to define the TGVs 216 extending through the glass core 204. In some examples, as shown in FIG. 7, the conductive material 702 is also deposited across the outer surfaces 504, 506 of the glass core 204. In some examples, the conductive material 702 is deposited via an electroplating process after the deposition of a metal seed layer (e.g., over the liner 210 and the exposed portions of the glass core 204 within the openings 502). In other examples, the TGVs 222 are plated from the bottom up. In such examples, the glass core 204 of FIG. 5 is first attached to a conductive carrier to provide metal at the bottom of the openings 502 to enable initiation of the plating process. In such examples, there may be no seed layer. The stage of fabrication represented in FIG. 7 is also after a polishing process (e.g., a CMP process) to flatten or even out the conductive material 702 on the outer surfaces 504, 506 of the glass core.

FIG. 8 represents the stage of fabrication following the removal (e.g., via etching) of selective portions of the conductive material 702 to define the conductive pads 220. In some examples, the selective portions of the conductive material 702 that are removed are defined through a photolithography process. In some examples, the second surface 506 of the glass core undergoes a polishing process (e.g., a CMP process) to make the both the dielectric material 208 and the TGVs 216 flush with the second surface 506. In some examples, the assembly also undergoes a cleaning process to remove any residue materials.

FIG. 9 represents the stage of fabrication following the application of the dielectric material 208 adjacent to the first surface 504 of the glass core 204. In some examples, the dielectric material 208 is applied through a lamination process. FIG. 9 also represents the result of adding openings 902 (e.g., holes) through the dielectric material 208 to expose the underlying conductive pads 220 associated with the TGVs 216. More particularly, in some examples, the openings 902 are provided through a drilling process (e.g., laser drilling).

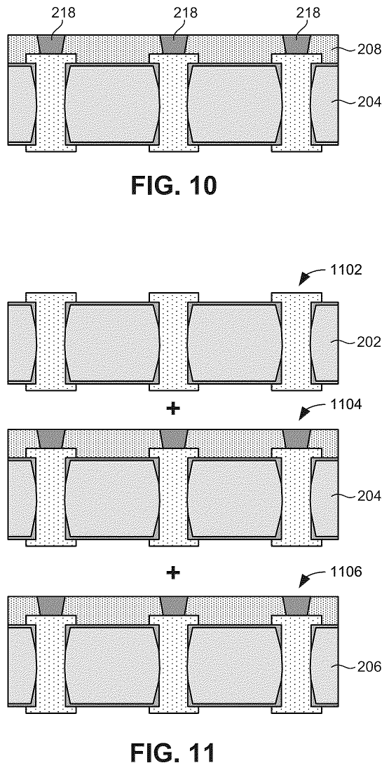

FIG. 10 represents the stage of fabrication following the deposition of the additional conductive material 218 into the openings 902 of the assembly shown in FIG. 9. In some examples the additional conductive material 218 is dispensed into the openings 902 as a liquid metal and/or paste (e.g., copper paste and/or other suitable metal (e.g., aluminum, nickel, tin, etc.)). In some examples, the additional conductive material 218 is deposited via a plating process. In some examples, excess amounts of the additional conductive material 218 (e.g., that extends beyond and/or above the outer surface of the dielectric material 208) is removed through a polishing process (e.g., a CMP process) to make the both the dielectric material 208 and the additional conductive material 218 flush with each other.

FIG. 11 represents the stage of fabrication when the three glass cores 202, 204, 206 are assembled or stacked together by combining or joining respective glass core assemblies 1102, 1104, 1106. In this example, each of the glass core assemblies 1102, 1104, 1106 of FIG. 11 are the result of processing the corresponding glass cores 202, 204, 206 through the stages of fabrication represented in FIGS. 3-10. That is, the second glass core 204 processed to the point represented in FIG. 10 corresponds to the second glass core assembly 1104 shown in FIG. 11. Further, as shown in FIG. 11, the third glass core assembly 1106 is substantially the same or identical to the second glass core assembly 1104 except for a different glass core (e.g., the third glass core 206 instead of the second glass core 204) with a different CTE. Likewise, the first glass core assembly 1102 is similar to the other two glass core assemblies 1104, 1106 except for the different glass core 202 (with different CTE) and the absence of the buffer layer 208 with the additional conductive material 218 disposed therein. That is, in some examples, the first glass core assembly 1102 of FIG. 11 is completed by the stage of fabrication represented in FIG. 8 (e.g., the fabrication processes discussed in connection with FIGS. 9 and 10 can be omitted). In some examples, once the different glass core assemblies 1102, 1104, 1106 are brought together (as represented in FIG. 11), the stack is pressed (e.g., subject to compression) and undergoes a curing process to join the assemblies. The final result of combining or joining the different glass core assemblies 1102, 1104, 1106 produces the substrate core 200 shown in FIG. 2.

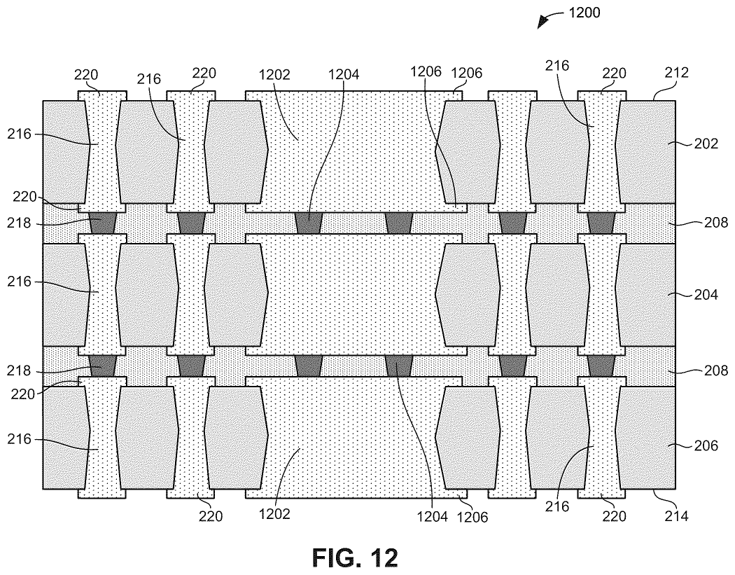

FIG. 12 illustrates another example substrate core 1200 that may be used to implement the example substrate core 128 of FIG. 1. The example substrate core 1200 of FIG. 12 is substantially the same as the example substrate core 200 of FIG. 2 except as noted below or otherwise made clear from the context. Accordingly, the features shown in FIG. 12 that are the same or similar to corresponding features in FIG. 2 (and associated FIGS. 3-11) are identified by the same reference numbers. Further, the description of such features described above in connection with FIG. 2 (and associated FIGS. 3-11) applies similarly with respect to the corresponding features in FIG. 12. For instance, as shown in FIG. 12, the example substrate core 1200 includes the glass cores 202, 204, 206 through which the TGVs 216 extend that include the conductive pads 220 at either end. Vertically adjacent ones of the TGVs 216 are electrically coupled by additional conductive material 218 that extends through intervening layers of dielectric material 208.

One difference between FIG. 12 and FIG. 2, is that the liner 210 is omitted. That is, in the illustrated example of FIG. 12, the TGVs 216 are plated directly onto the glass cores 202, 204, 206. In some such examples, the TGVs 216 include a seed layer that is directly in contact with the surface of the glass cores 202, 204, 206 to facilitate the plating of the bulk of the TGVs 216. In other examples, the seed layer is omitted (e.g., if the TGVs 216 are bottom-up plated). In some examples, the substrate core 1200 of FIG. 12 includes the liner 210 as discussed above in connection with FIG. 2.

FIG. 12 also differs from FIG. 2 in that the glass cores 202, 204, 206 include metal slugs 1202 disposed therein. As used herein, a metal slug is a relatively large mass of metal (e.g., larger than the TGVs 216) that can facilitate heat dissipation by providing a thermally conductive path for heat within a package substrate (e.g., the package substrate 110 of FIG. 1) to be conducted away from the substrate (e.g., towards an integrated heat spreader such as the package lid 112 in FIG. 1). The metal slugs 1202 may be used to implement the example metal slug 142 of FIG. 1. In the illustrated example of FIG. 12, the metal slugs 1202 in the separate glass cores 202, 204, 206 are thermally coupled by additional conductive material 1204 that extends through the intervening layers of the dielectric material 208. In this example, the additional conductive material 1204 coupling the metal slugs 1202 is substantially the same or identical to the additional conductive material 218 coupling the TGVs 216.

In the illustrated example of FIG. 12, the portions of the additional conductive material 1204 between adjacent metal slugs 1202 are shown as substantially the same size and spaced substantially the same distance apart as the additional conductive material 218 between adjacent TGVs 216. However, in other examples, the portions of the additional conductive material 1204 between adjacent metal slugs 1202 can be larger or smaller than what is shown and can be positioned closer or farther apart than what is shown. Further, although tow portions of the additional conductive material 1204 are between adjacent metal slugs 1202 in FIG. 12, in other examples, any other suitable number (e.g., 1, 2, 3, 4, 5, etc.) may be employed (which can depend on the size of the additional conductive material 1204 and the size of the associated metal slugs 1202).

In some examples, the fabrication of the example substrate core 1200 of FIG. 12 follows the same general process corresponding to the stages of fabrication represented in FIGS. 2-13. However, the laser induced deep etching (LIDE) process discussed above in connection with FIGS. 4 and 5 is modified to etch larger openings 502 in the glass core 204 corresponding to the size of the metal slugs 1202. The process otherwise proceeds as outlined above except that the addition of the liner (as detailed in connection with FIG. 6 is omitted). Notably, the depositing (e.g., plating) of the conductive material 702 in the openings 502 (as detailed in connection with FIG. 7) to provide the TGVs 216 will simultaneously provide the metal slugs 1202. Further, at the stage of fabrication represented in FIG. 8, the portions of the conductive material 702 to be removed are selected so define both conductive pads 220 (at the ends of the TGVs 216 adjacent the outer surfaces of the second glass core 204) as well as additional conductive pads 1206 at the end of metal slugs 142 as shown in FIG. 12.

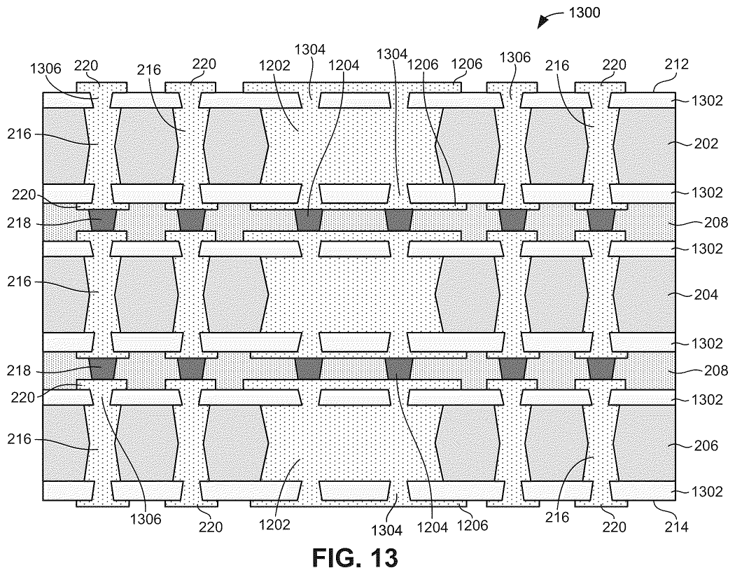

FIG. 13 illustrates another example substrate core 1300 that may be used to implement the example substrate core 128 of FIG. 1. The example substrate core 1300 of FIG. 13 is substantially the same as the example substrate cores 200, 1200 of FIGS. 2 and 12 except as noted below or otherwise made clear from the context. Accordingly, the features shown in FIG. 13 that are the same or similar to corresponding features in FIGS. 2 and 12 (and associated FIGS. 3-11) are identified by the same reference numbers. Further, the description of such features described above in connection with FIGS. 2 and 12 (and associated FIGS. 3-11) applies similarly with respect to the corresponding features in FIG. 13.

The example of FIG. 13 differs from the example of FIG. 12 in that buffer layers 1302 are added to the outer surfaces of each glass core 202, 204, 206 to separate the conductive pads 220, 1206 from the surfaces of the glass cores 202, 204, 206. Further, as shown in the illustrated example, the buffer layers 1302 are positioned between the glass cores 202, 204, 206 and the adjacent dielectric material 208 used to connect the different glass cores 202, 204, 206 together. In some examples, the buffer layers 1302 include a dielectric material that is applied through a lamination process. In some examples, the buffer layers 1302 are composed of the same material as the dielectric material 208. In other examples, the buffer layers 1302 are composed of a different material from the dielectric material 208.

As shown in FIG. 13, the conductive pads 1206 associated with the metal slugs 1202 are thermally coupled (e.g., electrically coupled) to the main body of the metal slugs 1202 by one or more conductive vias 1304 (e.g., copper vias) that extend through corresponding ones of the buffer layers 1302. Likewise, in this example, the conductive pads 220 associated with the TGVs 216 are electrically coupled to the main body of the TGVs 216 within the glass cores 202, 204, 206 by additional conductive vias 1306 (e.g., copper vias) that extend through corresponding ones of the buffer layers 1302. In the illustrating example of FIG. 13, the metal slugs 1202 are thermally coupled to the conductive pads 1206 through two conductive vias 1304. However, in other examples, any suitable number (e.g., 1, 2, 3, 4, 5, etc.) of conductive vias 1304 can be positioned between the metal slug 1202 and the corresponding conductive pads 1206. Further, the conductive vias 1304 can be any suitable size up to and including the same size as the metal slug 1202. In some examples, the buffer layer 1302 within the conductive vias 1306, as shown in FIG. 13, can be implemented in connection with the example substrate core 200 of FIG. 2.

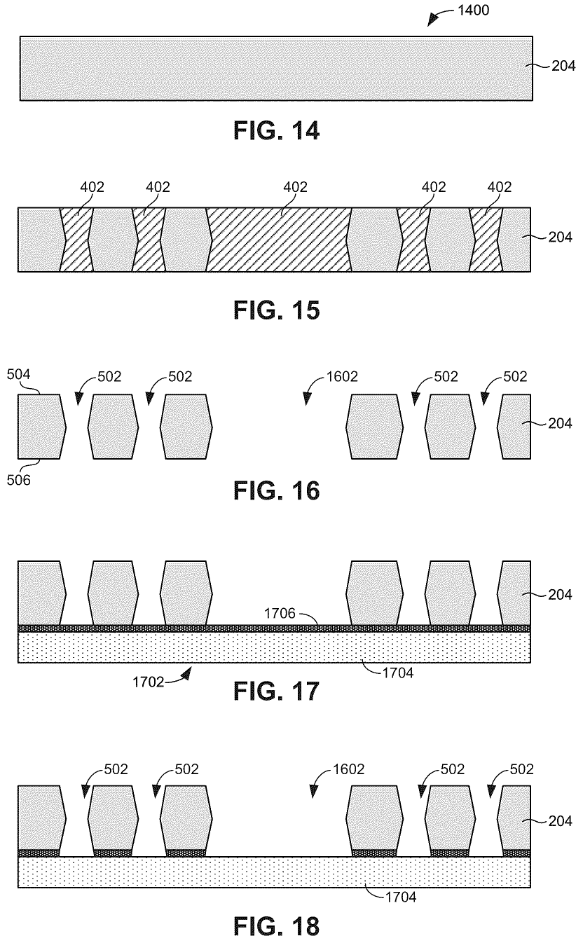

FIGS. 14-22 illustrate different stages in an example fabrication process to manufacture the example substrate core 1300 of FIG. 13. Many stages of fabrication represented in FIGS. 14-22 are similar or identical to the stages of fabrication discussed above in connection with FIGS. 3-11. Accordingly, similar reference numbers will be used for similar features and the description provided above applies in connection with FIGS. 14-22 except as noted or otherwise made clear from the context. FIG. 14 represents a glass panel 1400 corresponding to the initial state of any one of the glass cores 202, 204, 206. For purposes of explanation, the glass panel 1400 is shown and described as corresponding to the second glass core 204 (e.g., the middle glass core in the substrate core 1300 of FIG. 13) and is similar to the glass panel 300 of FIG. 3.

FIG. 15 represents the stage of fabrication following exposure of the glass core 204 to a laser as part of a laser induced deep etching (LIDE) process similar to what was described above in connection with FIG. 4. The laser is concentrated on defined regions 402 of the glass core 204 to modify the optical and chemical properties of the glass core 204 at those regions 402. FIG. 16 represents the stage of fabrication following a chemical etch process to remove the material in the modified regions 402 of the glass core 204 shown in FIG. 15 to define the openings 502 for the TGVs 216. Additionally, unlike what is shown in FIGS. 4 and 5, one of the regions 402 in FIG. 15 is much larger and results in a large second opening 1602 shown in FIG. 16. The large second opening 1602 serves as the basis for the metal slug 1202 of FIG. 13.

FIG. 17 represents the stage of fabrication following the glass core 204 being attached to a conductive carrier 1702. In this example, the conductive carrier includes a conductive layer 704 (e.g., a copper layer) and a release layer 706 (e.g., an adhesive dielectric layer). FIG. 18 represents the stage of fabrication following an etching process (e.g., a plasma etch, a dry etch) to remove portions of the release layer 1706 exposed within the openings 502, 1602 of the glass core 204, thereby exposing the underlying conductive layer 1704.

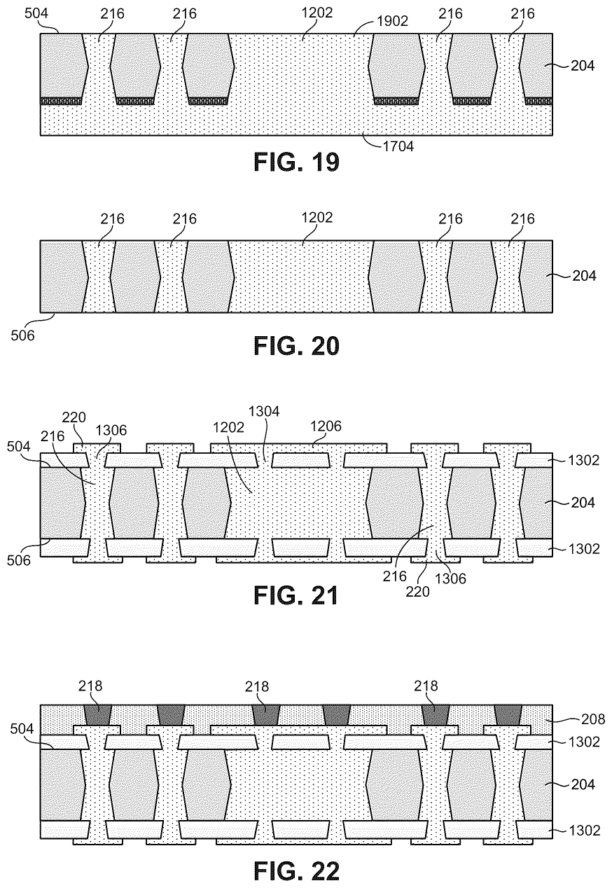

FIG. 19 represents the stage of fabrication following the depositing (e.g., plating) of conductive material 1902 (e.g., copper, aluminum, nickel, tin, etc.) within the openings 502, 1602 to define the TGVs 216 and the metal slug 1202 extending through the glass core 204. In this example, the TGVs 216 and the metal slug 1202 are plated up from the exposed portions of the conductive layer 1704. As such, in this example, there is no seed layer deposited along the walls of the openings 502, 1602 prior to the plating process. However, in other examples, a seed layer may be used to facilitate the plating of the TGVs 216 and the metal slug 1202. The stage of fabrication represented in FIG. 19 is also after a subsequent polishing process (e.g., a CMP process) to remove excess amounts of the conductive material 1902 that extends above the first surface 504 of the glass core 204. Thus, in some examples, both the TGVs 216 and the metal slug 1202 are flush with the first surface 604.

FIG. 20 represents the stage of fabrication following the removal of the conductive carrier 1702, including both the conductive layer 1704 and the release layer 1706. In some examples, the second surface 506 of the glass core undergoes a polishing process (e.g., a CMP process) to make the both the TGVs 216 and the metal slug 1202 flush with the second surface 506. In some examples, the assembly also undergoes a cleaning process to remove any residue materials.

FIG. 21 represents the stage of fabrication following the application of the buffer layers 1302 (e.g., adhesive layers, dielectric layers) on the respective first and second surfaces 504, 506 of the glass core 204. In some examples, the buffer layers 1302 are applied through a lamination process. FIG. 12 also represents the result of adding the conductive vias 1304, 1306 through the buffer layers 1302 to couple the underlying TGVs 216 and the metal slug 1202 to the associated conductive pads 220, 1206. More particular, holes (e.g., openings) are drilled through the buffer layers 1302 to expose the ends of the TGVs 216 and the metal slug 1202 and then the holes are filled (e.g., plated) to define the material of the conductive vias 1304, 1306 and to produce the conductive pads 220, 1206.

FIG. 22 represents the stage of fabrication following the application of the dielectric material 208 adjacent to the first surface 504 of the glass core 204 similar to the process described above in connection with FIG. 9. FIG. 22 also represents the additional conductive material 218 within the dielectric material 208 in a manner similar to what is described above in connection with FIGS. 9 and 10.

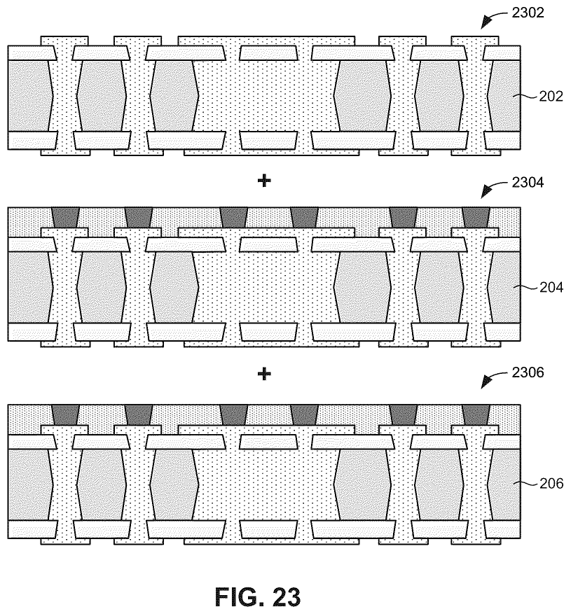

FIG. 23 represents the stage of fabrication when the three glass cores 202, 204, 206 are assembled or stacked together by combining or joining respective glass core assemblies 2302, 2304, 2306. In this example, each of the glass core assemblies 2302, 2304, 2306 of FIG. 23 are the result of processing the corresponding glass cores 202, 204, 206 through the stages of fabrication represented in FIGS. 14-22 similar to what is described above in connection with FIG. 11.

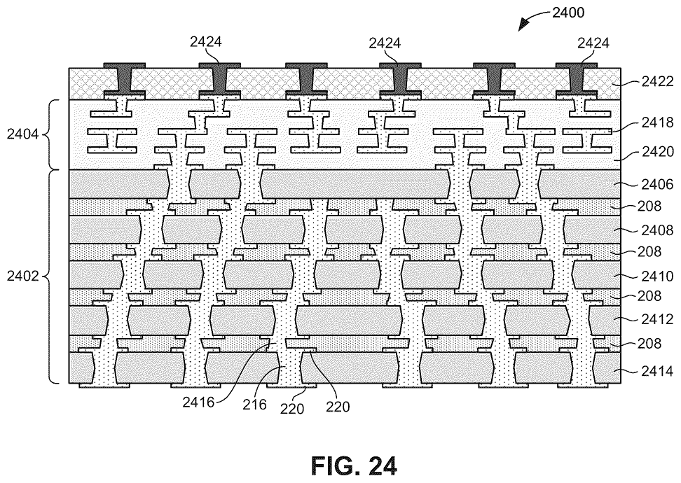

FIG. 24 illustrates a portion of example package substrate 2400 that may be used to implement the example package substrate 110 of FIG. 1. The example package substrate 2400 of FIG. 24 includes an example substrate core 2402 and an example fine line spacing (FLS) build-up region or layer 2404 (e.g., an FLS redistribution region or layer). The example substrate core 2402 may be used to implement the example substrate core 128 of FIG. 1 and the example FLS build-up region 2404 may be used to implement the example first build-up region 130 in FIG. 1. In this example, the second build-up region 131 of FIG. 1 is omitted. In other examples, the second build-up region 131 can be included (either using current lamination processes to add dielectric layers or to implement teachings disclosed herein to implement a FLS build-up region similar to the FLS build-up region 2404 shown in FIG. 24).

The example substrate core 2402 of FIG. 24 includes a stack of multiple different (e.g., disaggregated) glass cores (e.g., multiple glass layers, multiple glass core layers, etc.). More particularly, in this example, the stack includes five glass cores including a first glass core 2406 (e.g., a top glass core, an uppermost glass core), a second glass core 2408, a third glass core 2410 (e.g., a middle glass core), a fourth glass core 2412, and a fifth glass core 2414 (e.g., a bottom glass core, a lowermost glass core). In other examples, a different number of glass cores can be included in the stack. The different example glass cores 2406, 2308, 2410, 2412, 2414 of FIG. 24 correspond to the glass cores 132, 134, 136 of FIG. 1 (and/or the glass cores 202, 204, 206, 2406, 2308, 2410, 2412, 2414 of FIGS. 2, 12, 13, 24 and/or 36). Thus, the glass cores 2406, 2308, 2410, 2412, 2414 include different CTEs as described above to provide any suitable CTE gradient across the thickness of the overall substrate core 2402.

In the illustrated example of FIG. 24, the glass cores 2406, 2308, 2410, 2412, 2414 are the same or similar TGVs 216 as discussed above in connection with FIGS. 2-23. Thus, as shown in the illustrated examples, the TGVs 216 include conductive pads 220 at opposing ends of the TGVs 216 (adjacent opposing outer surfaces of the respective glass cores 2406, 2308, 2410, 2412, 2414). Adjacent pairs of the glass cores 2406, 2308, 2410, 2412, 2414 are separated by layers of the dielectric material 208 (e.g., adhesive material, adhesive resin) discussed above in connection with FIG. 2. In some examples, as discussed above, the layers of the dielectric material 208 between the glass cores 2406, 2308, 2410, 2412, 2414 function as redistribution layers with metallization layers that provide traces or routing extending between the glass cores (e.g., substantially parallel to the main planes of the glass cores) to define or redistribute electrical paths through the substrate core 2402. In this example, the redistribution layers defined by the metal within the dielectric material 208 includes conductive vias 2416 (e.g., copper vias) that extend through the dielectric material 208 to electrically coupled the TGVs 216. In some examples, the conductive vias 2416 can be implemented by the additional conductive material 218 discussed above in connection with FIG. 2.

The example FLS build-up region 2404 includes alternating metal layers 2418 and thin film dielectric layers 2420. In some examples, the thin film dielectric layers 2420 includes the same material as the dielectric material 208 between the glass cores 2406, 2308, 2410, 2412, 2414. In other examples, a different dielectric material is used. More particularly, in some examples, the thin film dielectric layers 2420 can be nano-filled ABF, high resolution thin dry film photo-imagable dielectrics (PIDs) or liquid film PIDs. In some examples, the thin film dielectric layers 2420 include polyimides. As noted above, current known approaches to fabricating build-up regions involve laminating layers of an epoxy-based dielectric material with intervening layers of metal (e.g., copper foil). The thickness of the dielectric layers in such known techniques is approximately 25 μm. Unlike these techniques, the dielectric material in the thin film dielectric layers 2420 is significantly less (e.g., a thickness of less than or equal to approximately 10 μm, less than or equal to approximately 5 μm, less than or equal to approximately 2 μm, less than or equal to approximately 1 μm, etc.). In some examples, such thin layers are achieved by depositing the dielectric material using thin film deposition techniques (e.g., PVD, CVD, ALD, etc.). The thin layers not only position the metal layers 2418 closer together but also enable the formation of traces or routing with relatively fine line spacing (e.g., 2 μm/2 μm line spacing, 1 μm/1 μm line spacing, etc.) to provide electrical paths (e.g., die-to-die interconnects) through the build-up region 2404 without the need for a silicon-based interconnect bridge (e.g., the interconnect bridge 126 of FIG. 1). That is, in some examples, the package substrate 2400 does not include a silicon-based interconnect bridge embedded therein to provide die-to-die interconnects.

As shown in the illustrated example, a solder resist layer 2422 is added onto the FLS build-up region 2404. In this example, the solder resist layer 2422 defines the uppermost surface of the package substrate 2400. That is, the solder resist layer 2422 defines the inner surface 122 of the package substrate 110 of FIG. 1 (e.g., one of the two opposing outer surfaces of the package substrate 110). In this example, the FLS build-up region 2404 spans a full distance between the first glass core 2406 and the solder resist layer 2422. In some examples, contact pads 2424 are provided along the outer surface of the solder resist layer 2422 that are electrically coupled to the metal layers 2418 within the FLS build-up region 2404. In this example, the contact pads 2424 correspond to the contact pads 120 of FIG. 1.

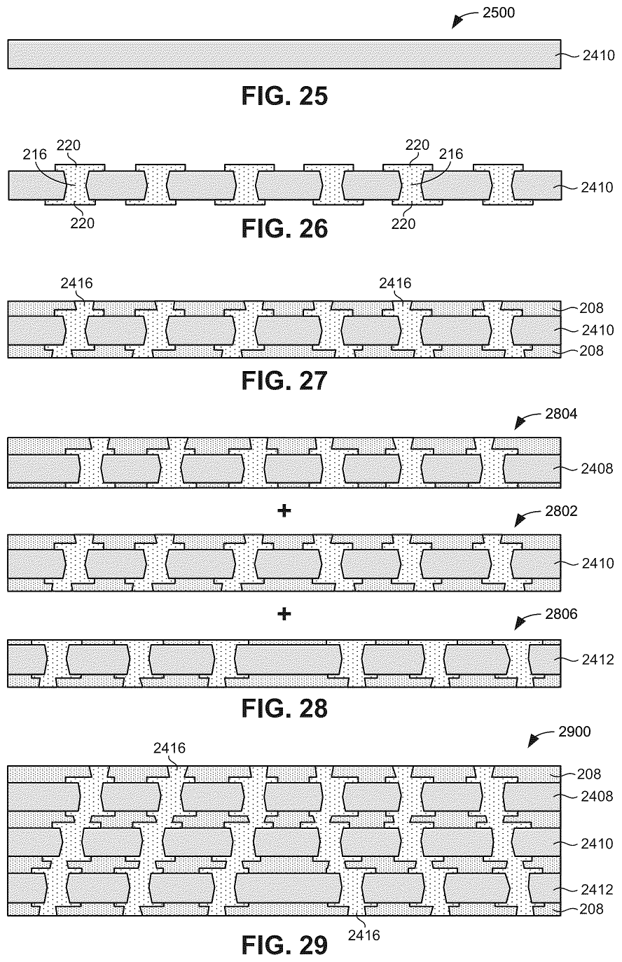

FIGS. 25-35 illustrate different stages in an example fabrication process to manufacture the example package substrate 2400 of FIG. 24. Many stages of fabrication represented in FIGS. 14-22 are similar or identical to the stages of fabrication discussed above in connection with FIGS. 3-11 and FIGS. 14-23. Accordingly, similar reference numbers will be used for similar features and the description provided above applies in connection with FIGS. 25-35 except as noted or otherwise made clear from the context. FIG. 25 represents a glass panel 2500 corresponding to the initial state of any one of the glass cores 2406, 2308, 2410, 2412, 2414. For purposes of explanation, the glass panel 2500 is shown and described as corresponding to the third glass core 2410 (e.g., the middle glass core in the substrate core 2402 of FIG. 24).

FIG. 26 represents the stage of fabrication following the providing the third glass core 2410 of FIG. 25 with TGVs 216 and associated conductive pads 220. In some examples, the process to provide the TGVs 216 and conductive pads 220 shown in FIG. 26 corresponds to the process detailed above in connection with FIGS. 4-8 and/or FIGS. 15-21.

FIG. 27 represents the stage of fabrication following the deposition of the dielectric material 208 to both sides of the third glass core 2410 of FIG. 26. Further, FIG. 27 represents the stage of fabrication following the adding of the conductive vias 2416 into the dielectric material. In some examples, the process to add the dielectric material 208 and the conductive vias 2416 corresponds to the process detailed above in connection with FIGS. 9 and 10 and/or FIG. 22.

FIG. 28 represents the stage of fabrication when each of the glass cores except for the outermost (e.g., top and bottom) glass cores (e.g., the three internal glass cores 2408, 2410, 2412 of the substrate core 2402 of FIG. 24) are assembled or stacked together by combining or joining the associated glass core assemblies 2802, 2804, 2806. In this example, each of the glass core assemblies 2802, 2804, 2806 of FIG. 28 are the result of processing the corresponding glass cores 2408, 2410, 2412 through the stages of fabrication represented in FIGS. 25-27. That is, the third glass core 2410 processed to the point represented in FIG. 27 corresponds to the first glass core assembly 2802 shown in FIG. 24. Further, as shown in FIG. 24, the dielectric material 208 added to the second glass core assembly 2804 is thinner and does not include the conductive vias 2416. Another difference between the first glass core assembly 2802 and the second glass core assembly 2804 is the position of the TGVs 216 and the associated conductive pads 220 (and any other metallization on the outer surfaces of the glass cores).

The third glass core assembly 2806 is similar to the second glass core assembly 2804 except for the different glass core 2412 (with different CTE) and the different placement of the TGVs 216 and associated conductive pads 220 (and any other metallization). In some examples, once the different glass core assemblies 2802, 2804, 2806 are brought together (as represented in FIG. 28), the stack is pressed (e.g., subject to compression) and undergoes a curing process to join the assemblies. The final result of combining or joining the different glass core assemblies 2802, 2804, 2806 produces the internal glass core stack-up assembly 2900 shown in FIG. 29.

In some examples, the second and third glass core assemblies 2804, 2806 are combined with the first glass core assembly 2802 prior to adding the conductive vias 2416 onto the second and third glass core assemblies 2804, 2806. That is, in some examples, the outermost layers of the dielectric material 208 shown in FIG. 29 and the associated conductive vias 2416 can be added after the three glass cores 2408, 2410, 2412 are joined together.

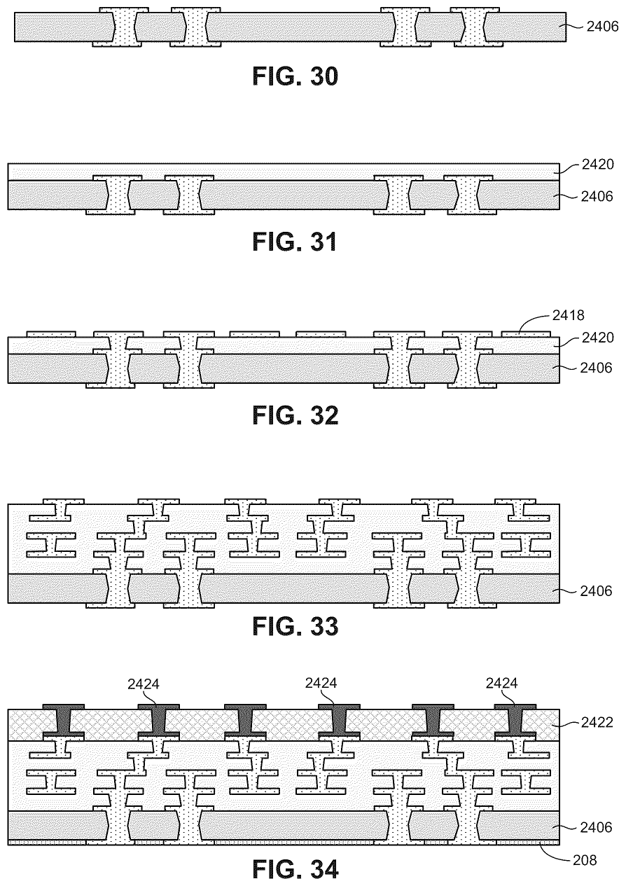

FIG. 30 represents the stage of fabrication following the processing of another glass panel associated with the first glass core 2406 up through the stage represented in FIG. 26 for the third glass core 2410 except for the different glass material (with different CTE) and the different placement of the TGVs 216 and associated conductive pads 220 (and any other metallization). In this example, the first glass core 2406 serves as the base substrate onto which the FLS build-up region 2404 is fabricated layer-by-layer. Using glass as the base substrate enables relatively flat surfaces (e.g., a relatively small total thickness variation of less than 10 μm) that can be precisely controlled so as to achieve relatively thin layers in the build-up region that can meet stringent via to pad overlay requirements for fin pitch scaling.

FIG. 31 represents the stage of fabrication following the addition of a first layer of the thin film dielectric layers 2420 onto the first glass core 2406 of FIG. 30. As discussed above, the thin film dielectric layers 2420 is added using a thin film deposition to achieve a thickness less than 10 μm (e.g., less than or equal to 5 μm, less than or equal to 2 μm, less than or equal to 1 μm, etc.). FIG. 32 represented the stage of fabrication following the addition conductive vias 3202 within the first layer of the thin film dielectric layers 2420 and the addition of a first layer of the metal layers 2418 onto the first layer of the thin film dielectric layers 2420. Adding alternating layers of the thin film dielectric and the metal can be repeated as many times as needed to complete the FLS build-up region 2404. FIG. 33 represents the stage of fabrication after completion of all layers in the FLS build-up region 2404.

FIG. 34 represents the stage of fabrication following the addition of the solder resist layer 2422 and the associated contact pads 2424. Further, in this example, a portion of the dielectric material 208 is added to the bottom side of the first glass core 2406 a first layer of the thin film dielectric layers 2420 onto the glass core 2406 of FIG. 30 in preparation to being joined together with the other glass cores 2408, 2410, 2412, 2414.

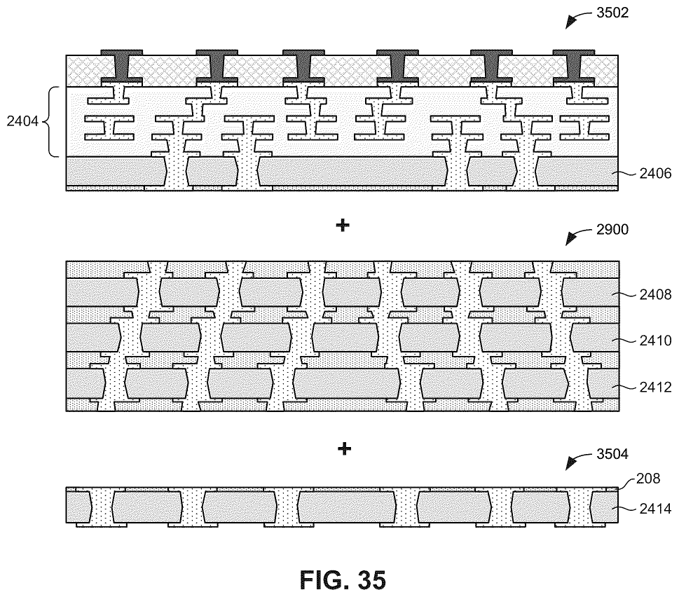

FIG. 35 represents the stage of fabrication when each of the glass cores 2406, 2408, 2410, 2412, 2414 are assembled or stacked together (along with the FLS build-up region 2404) by combining or joining an associated build-up region assembly 3502 with the internal glass core stack-up assembly 2900 of FIG. 29 and another glass core assembly 3504. In this example, the build-up region assembly 3502 of 35 corresponds to the end result of the process represented in FIG. 34. Further, the glass core assembly 3504 is the result of processing the fifth glass core 2414 through the stages of fabrication represented in FIGS. 25 and 26 and then adding a portion of the dielectric material 208 to facilitate the joining of the different assemblies 2900, 3502, 3504. The final result of combining or joining the different assemblies 2900, 3502, 3504 produces the package substrate 2400 shown in FIG. 24. In some examples, the assemblies 2900, 3502, 3504 can include different ones of the glass cores 2406, 2408, 2410, 2412, 2414 from what is shown in the illustrated example. For instance, in some examples, the first glass core 2406 can be combined with one or more underlying glass cores prior the fabrication of the FLS build-up region 2404. That is, in some examples, some or all of the glass cores 2406, 2408, 2410, 2412, 2414 in the substrate core 2402 may be combined and collectively serve as the base substrate for the FLS build-up region 2404.

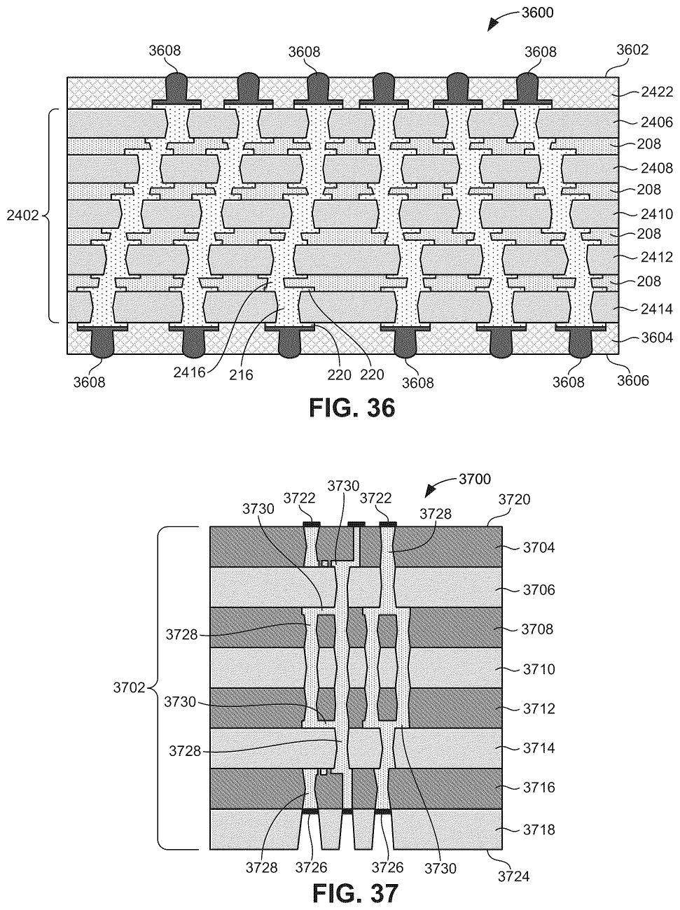

FIG. 36 illustrates another example package substrate 3600 that may be used to implement the example package substrate 110 of FIG. 1. The example package substrate 3600 of FIG. 36 is substantially the same as the example package substrate 2400 of FIG. 24 except as noted below or otherwise made clear from the context. Accordingly, the features shown in FIG. 36 that are the same or similar to corresponding features in FIG. 24 (and associated FIGS. 25-35) are identified by the same reference numbers. Further, the description of such features described above in connection with FIG. 24 (and associated FIGS. 25-35) applies similarly with respect to the corresponding features in FIG. 36. For instance, as shown in FIG. 36, the example package substrate 3600 includes the example substrate core 2402 with the stack of five glass cores 2406, 2408, 2410, 2412, 2414 as discussed above in connection with FIG. 24 (and associated FIGS. 25-35). Further, in this example, the glass cores 2406, 2408, 2410, 2412, 2414 include the TGVs 216 extending therethrough with conductive pads 220 at opposite ends. The TGVs 216 are electrically coupled by conductive vias 2416 extending through layers of the dielectric material 208 (e.g., an adhesive resin) between the different glass cores 2406, 2408, 2410, 2412, 2414.

The example of FIG. 36 differs from the example of FIG. 24 in that the example package substrate 3600 of FIG. 36 does not include the example FLS build-up region 2404 shown in FIG. 24. In fact, in the illustrated example of FIG. 36, there is no build-up region on either side of the substrate core 2402. Rather, as shown in the illustrated example of FIG. 36, the solder resist layer 2422 is provided adjacent to the outer facing surface of the first glass core 2406. The solder resist layer 2422 defines a first outer surface 3602 of the package substrate 3600 (e.g., corresponding to the inner surface 122 of the package substrate 110 of FIG. 1). Further, in this example, a second solder resist layer 3604 is provided adjacent the fifth glass core 2414 to define a second outer surface 3606 of the package substrate 3600 (e.g., corresponding to the outer surface 105 of the package substrate 110 of FIG. 1). In some examples, contacts 3608 (represented as bumps in this example) are provided along both of the solder resist layers 2422, 3604 that are electrically coupled to the TGVs 216. As shown, in this example, the stack of glass cores (e.g., the substrate core 2402) spans a full distance between the solder resist layers 2422, 3604 on outer surfaces of the package substrate 3600. In other words, in this example, there is no organic-based build-up region between the outermost glass cores (e.g., the first and fifth glass cores 2406, 2414) and corresponding outer surfaces 3602, 3606 of the package substrate 3600.

In some examples, the method of manufacturing the example package substrate 3600 of FIG. 36 generally follows the process detailed above in connection with the FIGS. 25-30, 34, and 35 (e.g., the stages of manufacture associated with the fabrication of the FLS build-up region 2404 are omitted). In the example of FIG. 36, the stack of glass cores 2406, 2408, 2410, 2412, 2414 with the intervening layers of dielectric material 208 function as redistribution layers to redistribute electrical paths through the package substrate 3600. Thus, as shown in the illustrated example, the TGVs 216 in the different glass cores 2406, 2408, 2410, 2412, 2414 are not necessarily vertically aligned but may be offset and electrically coupled by horizontally extending layers of metallization within the layers of dielectric material 208 (e.g., along the facing surfaces of the glass cores 2406, 2408, 2410, 2412, 2414).

FIG. 37 illustrates another example package substrate 3700 that may be used to implement the example package substrate 110 of FIG. 1. The example package substrate 3700 of FIG. 37 includes a substrate core 3702 that contains a stack of multiple different (e.g., disaggregated) glass cores (e.g., multiple glass layers, multiple glass core layers, etc.). More particularly, in this example, the stack includes eight glass cores including a first glass core 3704 (e.g., a top glass core, an uppermost glass core), a second glass core 3706, a third glass core 3708, a fourth glass core 3710, a fifth glass core 3712, a sixth glass core 3714, a seventh glass core 3716, and an eighth glass core 3718 (e.g., a bottom glass core, a lowermost glass core). In other examples, a different number of glass cores can be included in the stack. The different example glass cores 3704, 3706, 3708, 3710, 3712, 3714, 3716, 3718 of FIG. 34 can correspond to the glass cores 132, 134, 136 of FIG. 1 (and/or the glass cores 202, 204, 206, 2406, 2308, 2410, 2412, 2414 of FIGS. 2, 12, 13, 24 and/or 36). Thus, the glass cores 3704, 3706, 3708, 3710, 3712, 3714, 3716, 3718 include different CTEs as described above to provide any suitable CTE gradient across the thickness of the overall substrate core 3702. However, unlike the examples shown in FIGS. 1-36, the glass cores 3704, 3706, 3708, 3710, 3712, 3714, 3716, 3718 are directly abutting or in direct contact without an intervening layer of dielectric material or adhesive resin. To help distinguish the different layers, alternating ones of the glass cores are shown with a different shading or fill pattern in the illustrated example.

The example package substrate 3700 of FIG. 37 is similar to the example package substrate 3600 of FIG. 36 in that the package substrate 3700 does not include any build-up regions or redistribution layers outside of the glass-based substrate core 3702. Further, unlike what is shown in FIG. 36, the example package substrate 3700 of FIG. 37 does not include solder resist layers on the outer surfaces. Rather, the outer facing surface 3720 of the first glass core 3704 defines an outer surface of the package substrate 3700 (e.g., corresponding to the inner surface 122 of the package substrate 110 of FIG. 1). In this example, the outer facing surface 3720 of the first glass core 3704 includes contact pads 3722 corresponding to the contact pads 120 of FIG. 1. In a similar manner, the outer facing surface 3724 of the eighth glass core 3718 defines an outer surface of the package substrate 3700 (e.g., corresponding to the outer surface 105 of the package substrate 110 of FIG. 1). In this example, the eighth glass core 3718 includes recesses that expose additional contact pads 3726 corresponding to the contacts 104 of FIG. 1.

In the illustrated example of FIG. 37, the contact pads 3722, 3726 on opposing sides of the package substrate 3700 are electrically coupled by a series of TGVs 3728 and metal traces 3730 (e.g., metal routing) defined within the stack of glass cores 3704, 3706, 3708, 3710, 3712, 3714, 3716, 3718. The TGVs 3728 and the metal traces 3730 collectively define the interconnects 124 that extend through the package substrate 110 of FIG. 1. Thus, in this example, the substrate core 3702 functions as a redistribution layer to redistribute electrical paths between the contact pads 3722, 3726 on either side of the package substrate 3700.

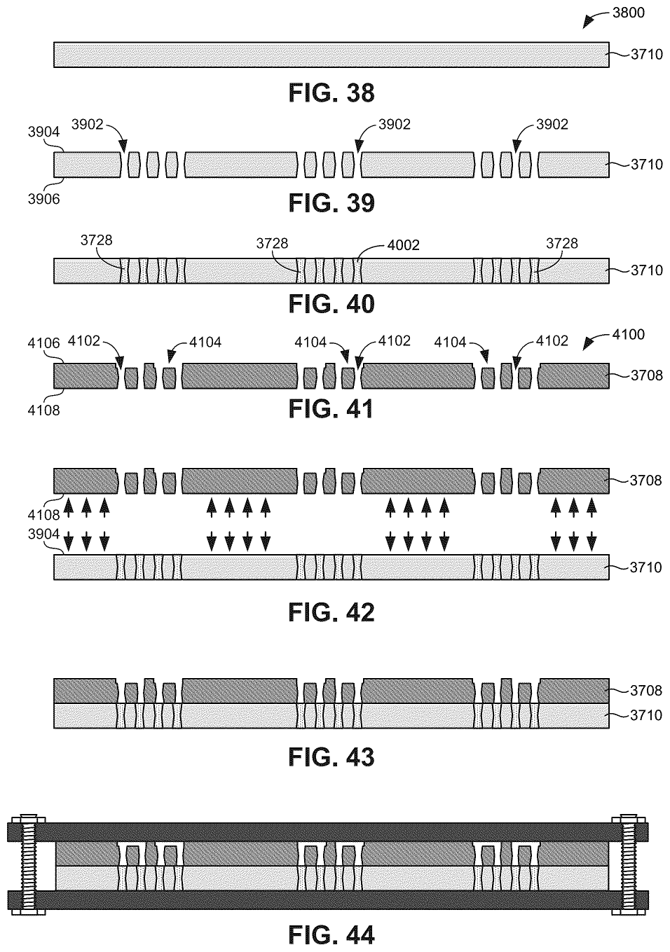

FIGS. 38-48 illustrate different stages in an example fabrication process to manufacture the example package substrate 3700 of FIG. 37. Many stages of fabrication represented in FIGS. 38-48 are similar or identical to the stages of fabrication discussed above in connection with FIGS. 3-11, 14-22, and 25-35. Accordingly, similar reference numbers will be used for similar features and the description provided above applies in connection with FIGS. 38-48 except as noted or otherwise made clear from the context. FIG. 38 represents a glass panel 3800 corresponding to the fourth glass core 3710. The glass panel 3800 can be the same or similar as any of the glass panel 300 of FIG. 3. FIG. 39 represents the stage of fabrication following the addition of through-holes 3902 in the glass core 3710 (e.g., through a LIDE process). As shown the through-holes 3902 extend all the way through the glass core 3170 between opposing first and second surfaces 3904, 3906 of the glass core 3710. FIG. 40 represents the stage of fabrication following the addition of conductive metal 4002 (e.g., copper, aluminum, nickel, tin, etc.) in the through-holes 3902 to define the TGVs 3728. The conductive metal 4002 can be deposited using any suitable process (e.g., depositing a seed layer and then plating, bottom-up plating (without seed layer), etc.). In some examples, a liner (e.g., the liner 210) is added to line the through-holes 3902 (partially or fully) prior to the deposition of the conductive metal 4002.

In some examples, the glass core 3710 with the TGVs 3728 (or the through-holes 3902 prior to being filled with the metal 4002) are fabricated through 3D printing. That is, in some examples, fine layers of glass powder are applied onto an underlying substrate up to a set thickness for the glass core and then the glass power is heated to melt and form a solid piece of glass. In some examples, the glass powder is layered or dispensed with open spaces corresponding to the locations of the through-holes 3902. Additionally or alternatively, in some examples, the 3D printing process includes depositing metal powder at the locations corresponding to the TGVs 3728 at the same time as the glass power is dispensed so that when the pattern of glass and metal powder is heated, a solid sheet of glass will form that already includes the TGVs 3728 provided therein by the bonding of the metal powder. In other examples, the glass core can be fabricated on an underlying surface through a spin coating process using a liquid containing glass particles that are subsequently heated to bond together and define the solid sheet of glass for the fourth glass core 3710. In some examples, a CMP process is employed to smooth out the surfaces of the glass core.

FIG. 41 represents the stage of fabrication following the processing of another glass panel 4100 corresponding to the third glass core 3708. More particularly, at this stage in the fabrication, the third glass core 3708 already includes additional through-holes 4102 that are to define locations for additional TGVs 3728. Further, in this example, the third glass core 3708 includes channels 4104 (e.g., trenches) that extend laterally along (e.g., parallel to) one or both outer surfaces 4106, 4108 of the third glass core 3708. In some examples, the fourth glass core 3710 may also include channels that are filled with the conductive metal 4002.

As shown in FIG. 37, the third and fourth glass cores 3708, 3710 directly abut one another with the lower surface 4108 of the third glass core 3708 interfacing with the upper surface 3904 of the fourth glass core 3710. Accordingly, FIG. 42 represents the stage of fabrication in which the interfacing surfaces are subject to an acid clean to remove impurities. FIG. 43 represents the stage of fabrication when the cleaned glass cores 3708, 3710 are brought together and attached with a pre-bond soak at an elevated temperature. FIG. 44 represents the stage of fabrication when the combined glass cores 3708, 3710 are compressed at an elevated temperature to complete the fusion bonding process of the two glass cores. In some examples, the glass cores 3708, 3710 are bonded using ultrasonic bonding techniques.

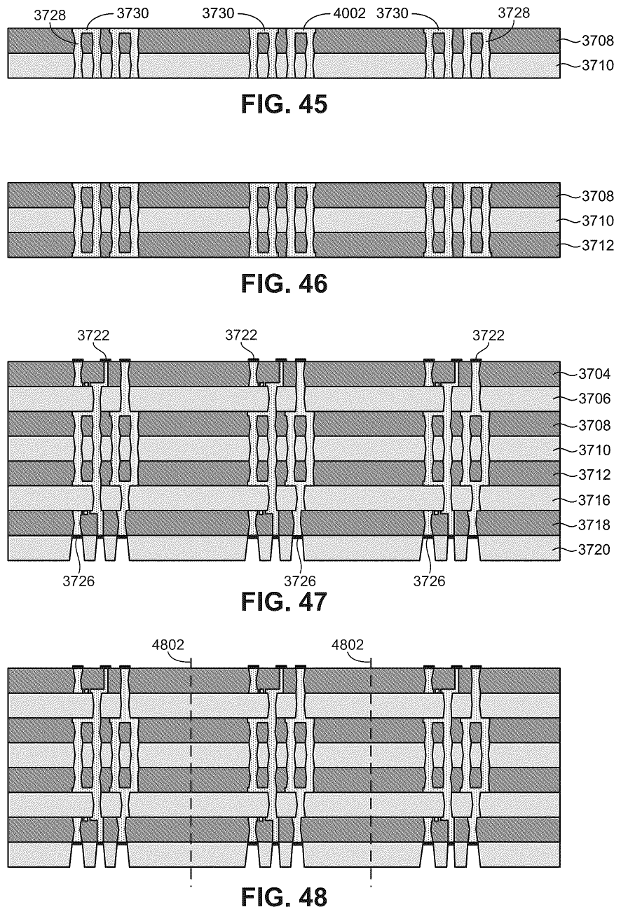

FIG. 45 represents the stage of fabrication following the addition of an additional amount of the conductive metal 4002 to fill the openings (e.g., the through-holes 4102 and the channels 4104) in the third glass core 3708. In this manner, the TGVs 3728 and the traces 3730 in the third glass core 3708 are defined. In some examples, the openings in the third glass core 3708 can be filled with conductive metal 4002 prior to the third glass core 3708 being bonded to the fourth glass core 3710. In some such examples, the metal within the separate glass cores 3708, 3710 may also form fusion bonds during the bonding process represented in FIG. 44. In other examples, both glass cores 3708, 3710 may be bonded together prior to either of the glass cores 3708, 37190 including the conductive metal 4002. In some such examples, the conductive metal 4002 can be added to the openings in both glass cores 3708, 3710 at the same time after being combined together.

In some examples, the third glass core 3708 is fabricated and processed independent of the fourth glass core 3710. Thus, in some examples, the different glass cores 3708, 3710 are fabricated and process in parallel before being bonded together as shown in FIG. 44. In other examples, the third glass core 3708 is fabricated (e.g., 3D printed, spin coating, etc.) directly on the previously fabricated fourth glass core 3710. In some examples, the manner in which individual glass cores are fabricated and combined (whether beginning with a solid glass panel, or whether the glass core is fabricated through 3D printing or spin coating, and whether such is done on a previously fabricated glass core) can depend on the nature of the overall stack-up intended as the associated material stress state requirements and heat affected zones. For instance, a relatively thin glass layer (e.g., less than 50 μm) can more easily be achieved using 3D printing. However, 3D printing may deleteriously contribute to heat affected zones. Thus, tradeoffs between different processing techniques can be made.

FIG. 46 represents the stage of fabrication following the joining of the fifth glass core 3712 to the fourth glass core 3710 on the side opposite to the third glass core 3708. In some examples, the addition of the fifth glass core 3712 follows the process for the third glass core 3708 detailed above in connection with FIGS. 41-45. This process can be repeated for every other glass core until you have a full stack-up of all glass cores 3704, 3706, 3708, 3710, 3712, 3714, 3716, 3718 as represented in FIG. 47. As noted above, in some examples, the openings in individual glass cores can be filled with metal before or after they are combined with other glass cores. In some examples, multiple (e.g., some or all) glass cores can be combined together before metal is added with the metal being added (e.g., plated) for the multiple glass cores later on in a single plating process. FIG. 47 also represents the result of the subsequent addition of the conductive pads 3722, 3726. In some examples, the conductive pads 3722, 3726 are added prior to the full stack of glass cores 3704, 3706, 3708, 3710, 3712, 3714, 3716, 3718 being combined or joined together.

In some examples, different sets or groups of the glass cores 3704, 3706, 3708, 3710, 3712, 3714, 3716, 3718 can be combined together before being combined into the full stack. That is, while one additional glass core can be added to all previously combined glass cores until the full stack is completed, in other examples, different groups of the glass cores can be combined together and then those groups combined to form the full stack. Additionally or alternatively, in some examples, more than two separate glass cores and/or separate groups of bonded glass cores can be combined and bonded together at one time. For instance, in some examples, each of the third, fourth, and fifth glass cores 3708, 3710, 3712 can be separately fabricated and then compressed together (as in FIG. 44) all at once rather than bonding two glass cores first and then bonding the third to the other two. In some examples, all of the glass cores 3704, 3706, 3708, 3710, 3712, 3714, 3716, 3718 are separately fabricated and all are stacked together and bonded together at the same time.

FIG. 48 represents the stage of fabrication associated with the singulation of the stack of glass panels (corresponding to the different glass cores 3704, 3706, 3708, 3710, 3712, 3714, 3716, 3718) into individual units. Specifically, FIG. 48 shows saw lines 4802 (e.g., saw streets, cut lines, etc.) along which a singulating saw runs to separate different units. A single one of the resulting units corresponds to the example package substrate 3700 shown in FIG. 37.

The foregoing examples of the package substrates 110, 2400, 3600, 3700 and the associated substrate cores 128, 200, 1200, 1300, 2402, 3702 of FIGS. 1-48 teach or suggest different features and describe different methods of manufacture. Although each example package substrate 110, 2400, 3600, 3700 and the associated substrate cores 128, 200, 1200, 1300, 2402, 3702 disclosed above has certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features. Furthermore, any of the example fabrication processes used to produce any of the example package substrates 110, 2400, 3600, 3700 and/or the associated substrate cores 128, 200, 1200, 1300, 2402, 3702 can be suitably adapted to produce any of other package substrates 110, 2400, 3600, 3700 and/or the associated substrate cores 128, 200, 1200, 1300, 2402, 3702

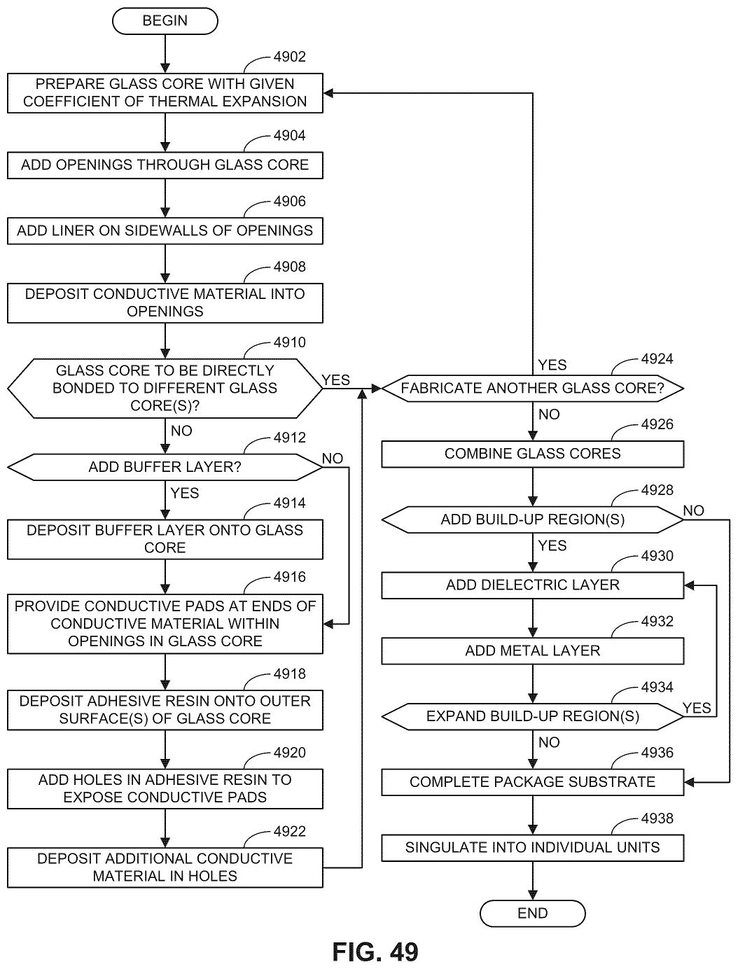

FIG. 49 is a flowchart representative of an example method of manufacturing any one of the example package substrates 110, 2400, 3600, 3700 including any one of the example substrate cores 128, 200, 1200, 1300, 2402, 3702 of FIGS. 1-48. In some examples, some or all of the operations outlined in the example method of FIG. 48 are performed automatically by fabrication equipment that is programmed to perform the operations. Although the example method of manufacture is described with reference to the flowchart illustrated in FIG. 48, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method of FIG. 49 begins at block 4902 by preparing a glass core (e.g., anyone of the example glass cores 202, 204, 206, 2406, 2308, 2410, 2412, 2414, 3704, 3706, 3708, 3710, 3712, 3714, 3716, 3718) with a given coefficient of thermal expansion (CTE). In some examples, the composition of materials used in the glass core is selected to achieve the CTE intended for a particular layer of glass within an overall substrate core that includes multiple glass cores stacked together. At block 4904, the example method includes adding openings through glass core (e.g., as represented in FIGS. 5, 16, 39, and 41). The openings can include openings for TGVs (e.g., the TGVs 238, 3728), metal slugs (e.g., the metal slug 1202), and/or metal traces (e.g., the metal traces 3730).

At block 4906, the example method involves adding a liner on sidewalls of the openings (e.g., the liner 210 discussed above in connection with FIG. 6). In some examples, block 4906 is omitted. At block 4908, the example method involves depositing conductive material into openings (e.g., as discussed in connection with FIGS. 7, 17-20, and 40). In some examples, this involves depositing a seed layer followed by an additional plating process. In some examples, this involves a bottom-up plating process (e.g., from an underlying conductive carrier) without a seed layer. In some examples, blocks 4902, 4904, and 4908 are implemented concurrently as part of a 3D printing process. At block 4910, the example method involves determining whether the glass core is to be directly bonded to different glass cores (e.g., via fusion bonding, ultrasonic bonding, etc.). If so, the method advances to block 4924. Otherwise, the method advances to block 4912.

At block 4912, the example method involves determining whether to add a buffer layer (e.g., the buffer layer 1302 of FIG. 13). If so, the method advances to block 4914 where a buffer layer is added (e.g., laminated) onto the glass core (e.g., as discussed in connection with FIGS. 9, 22, 27, 34, 35). Thereafter, the method advances to block 4916. If the method determines (at block 4912) that no buffer layer is to be added, the method advances directly to block 4916.

At block 4916, the example method involves providing conductive pads (e.g., the conductive pads 220) at ends of the conductive material within the openings in the glass core. In some examples, this is accomplished by selectively removing (e.g., via etching) excess amounts of the conductive material deposited at block 4908 (e.g., as discussed in connection with FIGS. 7 and 8). In other examples, block 4916 involves the deposition (e.g., plating) of more conductive material (e.g., as discussed in connection with FIG. 21).

At block 4918, the example method involves depositing an adhesive resin (e.g., the dielectric material 208) onto one or both of the outer surfaces of the glass core (e.g., as described in connection with FIGS. 9, 22, 27, and 35). At block 4920, the example method involves adding holes (e.g., the openings 902) in the adhesive resin to expose the conductive pads (e.g., as discussed in connection with FIG. 9). At block 4922, the example method involves depositing additional conductive material (e.g., the conductive material 218 and/or the metal vias 2416) in the holes (e.g., as discussed in connection with FIGS. 10, 22, 27). In some examples, the additional conductive material is a liquid metal or paste dispensed within the holes. In other examples, the additional conductive material is plated within the holes.

At block 4924, the example method involves determining whether to fabricate another glass core. If so, the method returns to block 4902 to repeat the process for a different glass core. In some examples, the different glass core can be constructed with a different CTE. In some examples, the next glass core is fabricated directly onto the previously fabricated glass core (e.g., via 3D printing, spin coating, etc.). In other examples, the next glass core is fabricated independent of the previously fabricated glass core. Accordingly, in some examples, separate iterations through the example process can be performed in parallel rather than sequentially. Once there are no further glass cores to fabricate, the example method advances to block 4926 that involves combining the glass cores. In some examples, if the glass cores are to be directly bonded (as determined at block 4910), the glass cores are cleaned, pre-soaked, and then compressed at an elevated temperature to produce fusion bonds (e.g., as discussed in connection with FIGS. 42-43). In other examples, the adhesive resin (added at block 4918) is used to attach the different glass cores together (e.g., as discussed in connection with FIGS. 10, 11, 23, 24, 27-29, and 35). In some examples, two or more glass cores are combined (at block 4926) before determining to fabricate additional glass cores (determined at block 4924). In some examples, at least some of the conductive material added at block 4908 and/or at block 4916 can be added after the glass cores are combined at block 4926.

At block 4928, the example method involves determining whether to add build-up regions (e.g., the build-up regions 130, 131, the FLS build-up region 2404). If so, the method advances to block 4930 where a dielectric layer is added. In some examples, the dielectric layer is an organic epoxy-based dielectric that is laminated onto the glass core. In some examples, the dielectric layer is a thin film dielectric layer (e.g., the dielectric layer 2420) to produce an FLS build-up region (e.g., the FLS build-up region 2404 as discussed in connection with FIGS. 24 and 31-33).

At block 4932, the example method involves adding a metal layer (e.g., the metal layer 2418) over the dielectric layer. In some examples, the metal layer is patterned to define traces or routing. In some examples, metal vias are added to extend through the underlying dielectric layer to electrically couple the metal layer to metal underneath the underlying dielectric layer. At block 4934, the example method involves determining whether to expand the build-up region(s) (e.g., determine whether to add another metallization layer with intervening dielectric layer). If so, the method returns to block 4930. Otherwise, the method advances to block 4936. Returning to block 4928, if the method determines not to add a build-up region (e.g., as in the example package substrates 3600, 3700 of FIGS. 36 and 37), the method advances directly to block 4936.

At block 4936, the example method involves completing the package substrate. In some examples, this includes combining different portions of the package substrate (e.g., that were not combined at block 4926). For instance, in some examples, the FLS build-up region is fabricated on one or more glass cores fabricated independent of other glass cores in a stack for an overall substrate core. In such examples, the glass core(s) with the FLS build-up region may be combined with other glass cores combined previously (e.g., as discussed in connection with FIG. 35). Further, in some examples, completing the package substrate includes adding solder resist layers (e.g., the solder resist layers 2422, 3604 discussed in connection with FIGS. 24, 34, and 36). Additionally or alternatively, in some examples, completing the package substrate includes adding contacts on the external surfaces of the package substrate (e.g., the conductive pads 2424 of FIG. 24, the contacts 3608 of FIG. 36, and/or the contact pads 3722, 3726 of FIG. 37). In some examples, the method is implemented at the panel level. Accordingly, at block 4938, the example method involves singulating the complete package substrate assembly into individual units (e.g., as discussed in connection with FIG. 48). Thereafter, the example method of FIG. 49 ends.

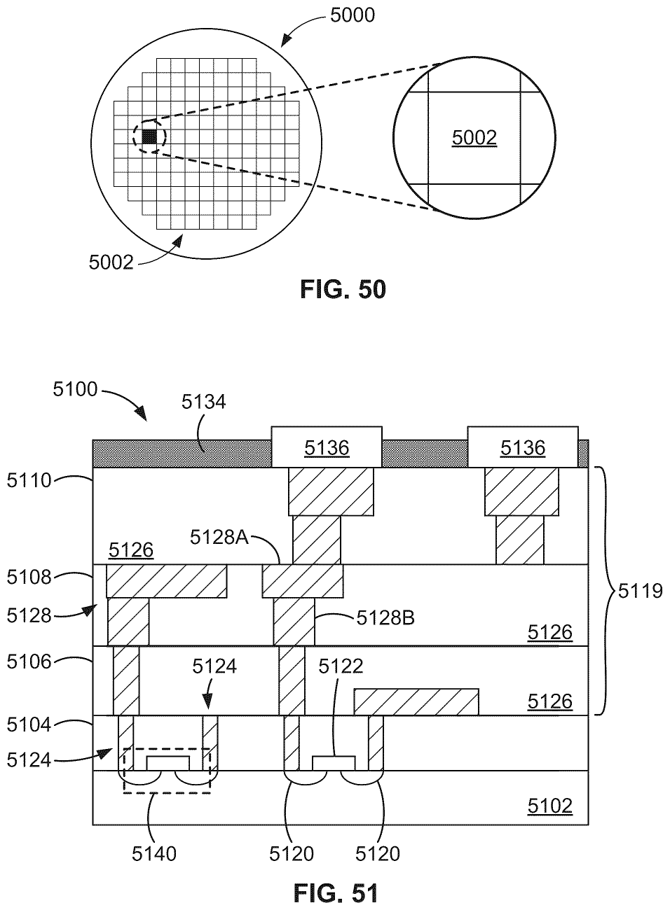

The example IC package 100 disclosed herein (including any one of the example package substrates 110, 2400, 3600, 3700 and associated substrate cores 128, 200, 1200, 1300, 2402, 3702) may be included in any suitable electronic component. FIGS. 50-53 illustrate various examples of apparatus that may include or be included in the IC package 100 disclosed herein.

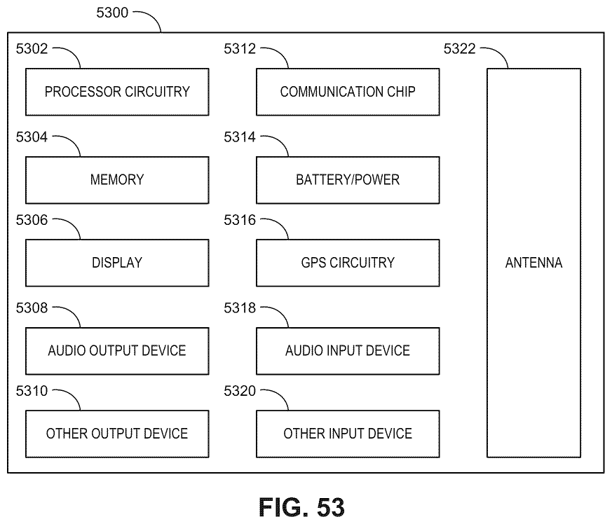

FIG. 50 is a top view of a wafer 5000 and dies 5002 that may be included in the IC package 100 of FIG. 1 (e.g., as any suitable ones of the dies 106, 108). The wafer 5000 includes semiconductor material and one or more dies 5002 having circuitry. Each of the dies 5002 may be a repeating unit of a semiconductor product. After the fabrication of the semiconductor product is complete, the wafer 5000 may undergo a singulation process in which the dies 5002 are separated from one another to provide discrete “chips.” The die 5002 includes one or more transistors (e.g., some of the transistors 5140 of FIG. 51, discussed below), supporting circuitry to route electrical signals to the transistors, passive components (e.g., traces, resistors, capacitors, inductors, and/or other circuitry), and/or any other components. In some examples, the die 5002 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 5002. For example, a memory array of multiple memory circuits may be formed on a same die 5002 as programmable circuitry (e.g., the processor circuitry 5302 of FIG. 53) and/or other logic circuitry. Such memory may store information for use by the programmable circuitry. The example IC package 100 disclosed herein may be manufactured using a die-to-wafer assembly technique in which some dies are attached to a wafer 5000 that includes others of the dies, and the wafer 5000 is subsequently singulated.

FIG. 20 is a cross-sectional side view of an IC device 2000 that may be included in the example IC package 100 (e.g., in any one of the dies 106, 108). One or more of the IC devices 5100 may be included in one or more dies 5002 (FIG. 50). The IC device 5100 may be formed on a die substrate 5102 (e.g., the wafer 5000 of FIG. 50) and may be included in a die (e.g., the die 5002 of FIG. 50). The die substrate 5102 may be a semiconductor substrate including semiconductor materials including, for example, n-type or p-type materials systems (or a combination of both). The die substrate 5102 may include, for example, a crystalline substrate formed using a bulk silicon or a silicon-on-insulator (SOI) substructure. In some examples, the die substrate 5102 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 5102. Although a few examples of materials from which the die substrate 5102 may be formed are described here, any material that may serve as a foundation for an IC device 5100 may be used. The die substrate 5102 may be part of a singulated die (e.g., the dies 5002 of FIG. 50) or a wafer (e.g., the wafer 5000 of FIG. 50).

The IC device 5100 may include one or more device layers 5104 disposed on and/or above the die substrate 5102. The device layer 5104 may include features of one or more transistors 5140 (e.g., metal oxide semiconductor field-effect transistors (MOSFETs)) formed on the die substrate 5102. The device layer 5104 may include, for example, one or more source and/or drain (S/D) regions 5120, a gate 5122 to control current flow between the S/D regions 5120, and one or more S/D contacts 5124 to route electrical signals to/from the S/D regions 5120. The transistors 5140 may include additional features not depicted for the sake of clarity, such as device isolation regions, gate contacts, and the like. The transistors 5140 are not limited to the type and configuration depicted in FIG. 51 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 5140 may include a gate 5122 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 5140 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 5140 along the source-channel-drain direction, the gate electrode may include a U-shaped structure that includes a bottom portion substantially parallel to the surface of the die substrate 5102 and two sidewall portions that are substantially perpendicular to the top surface of the die substrate 5102. In other examples, at least one of the metal layers that form the gate electrode may be a planar layer that is substantially parallel to the top surface of the die substrate 5102 and does not include sidewall portions substantially perpendicular to the top surface of the die substrate 5102. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 5120 may be formed within the die substrate 5102 adjacent to the gate 5122 of corresponding transistor(s) 5140. The S/D regions 5120 may be formed using an implantation/diffusion process or an etching/deposition process, for example. In the former process, dopants such as boron, aluminum, antimony, phosphorous, or arsenic may be ion-implanted into the die substrate 5102 to form the S/D regions 5120. An annealing process that activates the dopants and causes them to diffuse farther into the die substrate 5102 may follow the ion-implantation process. In the latter process, the die substrate 5102 may first be etched to form recesses at the locations of the S/D regions 5120. An epitaxial deposition process may then be carried out to fill the recesses with material that is used to fabricate the S/D regions 5120. In some implementations, the S/D regions 5120 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 5120 may be formed using one or more alternate semiconductor materials such as germanium or a group III-V material or alloy. In further examples, one or more layers of metal and/or metal alloys may be used to form the S/D regions 5120.

Electrical signals, such as power and/or input/output (I/O) signals, may be routed to and/or from the devices (e.g., transistors 5140) of the device layer 5104 through one or more interconnect layers disposed on the device layer 5104 (illustrated in FIG. 51 as interconnect layers 5106-2010). For example, electrically conductive features of the device layer 5104 (e.g., the gate 5122 and the S/D contacts 5124) may be electrically coupled with the interconnect structures 5128 of the interconnect layers 5106-2010. The one or more interconnect layers 5106-2010 may form a metallization stack (also referred to as an “ILD stack”) 5119 of the IC device 5100.

The interconnect structures 5128 may be arranged within the interconnect layers 5106-2010 to route electrical signals according to a wide variety of designs (in particular, the arrangement is not limited to the particular configuration of interconnect structures 5128 depicted in FIG. 51). Although a particular number of interconnect layers 5106-2010 is depicted in FIG. 51, examples of the present disclosure include IC devices having more or fewer interconnect layers than depicted.

In some examples, the interconnect structures 5128 may include lines 5128a and/or vias 5128b filled with an electrically conductive material such as a metal. The lines 5128a may be arranged to route electrical signals in a direction of a plane that is substantially parallel with a surface of the die substrate 5102 upon which the device layer 5104 is formed. For example, the lines 5128a may route electrical signals in a direction in and/or out of the page from the perspective of FIG. 51. The vias 5128b may be arranged to route electrical signals in a direction of a plane that is substantially perpendicular to the surface of the die substrate 5102 upon which the device layer 5104 is formed. In some examples, the vias 5128b may electrically couple lines 5128a of different interconnect layers 5106-2010 together.

The interconnect layers 5106-2010 may include a dielectric material 5126 disposed between the interconnect structures 5128, as shown in FIG. 51. In some examples, the dielectric material 5126 disposed between the interconnect structures 5128 in different ones of the interconnect layers 5106-2010 may have different compositions; in other examples, the composition of the dielectric material 5126 between different interconnect layers 5106-2010 may be the same.

A first interconnect layer 5106 (referred to as Metal 1 or “M1”) may be formed directly on the device layer 5104. In some examples, the first interconnect layer 5106 may include lines 5128a and/or vias 5128b, as shown. The lines 5128a of the first interconnect layer 5106 may be coupled with contacts (e.g., the S/D contacts 5124) of the device layer 5104.

A second interconnect layer 5108 (referred to as Metal 2 or “M2”) may be formed directly on the first interconnect layer 5106. In some examples, the second interconnect layer 5108 may include vias 5128b to couple the lines 5128a of the second interconnect layer 5108 with the lines 5128a of the first interconnect layer 5106. Although the lines 5128a and the vias 5128b are structurally delineated with a line within each interconnect layer (e.g., within the second interconnect layer 5108) for the sake of clarity, the lines 5128a and the vias 5128b may be structurally and/or materially contiguous (e.g., simultaneously filled during a dual-damascene process) in some examples.

A third interconnect layer 5110 (referred to as Metal 3 or “M3”) (and additional interconnect layers, as desired) may be formed in succession on the second interconnect layer 5108 according to similar techniques and/or configurations described in connection with the second interconnect layer 5108 or the first interconnect layer 5106. In some examples, the interconnect layers that are “higher up” in the metallization stack 5119 in the IC device 5100 (i.e., further away from the device layer 5104) may be thicker.

The IC device 5100 may include a solder resist material 5134 (e.g., polyimide or similar material) and one or more conductive contacts 5136 formed on the interconnect layers 5106-2010. In FIG. 51, the conductive contacts 5136 are illustrated as taking the form of bond pads. The conductive contacts 5136 may be electrically coupled with the interconnect structures 5128 and configured to route the electrical signals of the transistor(s) 5140 to other external devices. For example, solder bonds may be formed on the one or more conductive contacts 5136 to mechanically and/or electrically couple a chip including the IC device 5100 with another component (e.g., a circuit board). The IC device 5100 may include additional or alternate structures to route the electrical signals from the interconnect layers 5106-2010; for example, the conductive contacts 5136 may include other analogous features (e.g., posts) that route the electrical signals to external components.

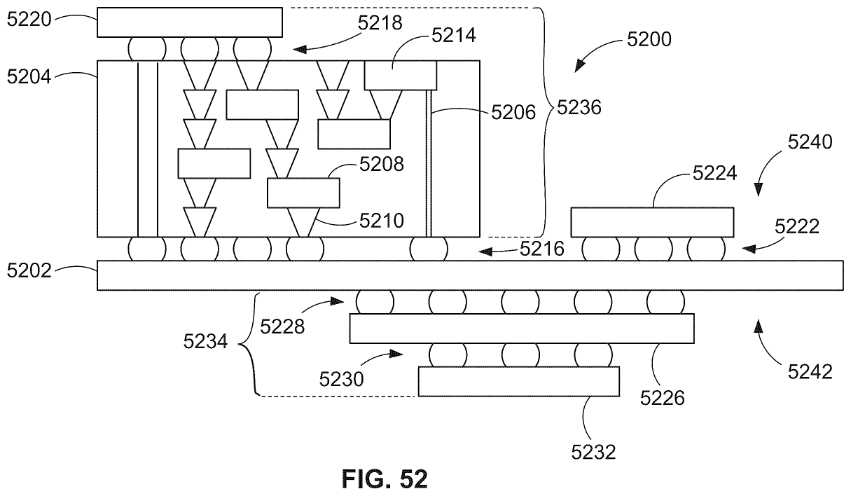

FIG. 52 is a cross-sectional side view of an IC device assembly 5200 that may include the IC package 100 disclosed herein. In some examples, the IC device assembly corresponds to the IC package 100. The IC device assembly 5200 includes a number of components disposed on a circuit board 5202 (which may be, for example, a motherboard). The IC device assembly 5200 includes components disposed on a first face 5240 of the circuit board 5202 and an opposing second face 5242 of the circuit board 5202; generally, components may be disposed on one or both faces 5240 and 5242. Any of the IC packages discussed below with reference to the IC device assembly 2200 may take the form of the example IC package 100 of FIG. 1.

In some examples, the circuit board 5202 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 5202. In other examples, the circuit board 5202 may be a non-PCB substrate.

The IC device assembly 5200 illustrated in FIG. 52 includes a package-on-interposer structure 5236 coupled to the first face 5240 of the circuit board 5202 by coupling components 5216. The coupling components 5216 may electrically and mechanically couple the package-on-interposer structure 5236 to the circuit board 5202, and may include solder balls (as shown in FIG. 52), male and female portions of a socket, an adhesive, an underfill material, and/or any other suitable electrical and/or mechanical coupling structure.

The package-on-interposer structure 5236 may include an IC package 5220 coupled to an interposer 5204 by coupling components 5218. The coupling components 5218 may take any suitable form for the application, such as the forms discussed above with reference to the coupling components 5216. Although a single IC package 5220 is shown in FIG. 52, multiple IC packages may be coupled to the interposer 5204; indeed, additional interposers may be coupled to the interposer 5204. The interposer 5204 may provide an intervening substrate used to bridge the circuit board 5202 and the IC package 5220. The IC package 5220 may be or include, for example, a die (the die 5002 of FIG. 50), an IC device (e.g., the IC device 5100 of FIG. 51), or any other suitable component. Generally, the interposer 5204 may spread a connection to a wider pitch or reroute a connection to a different connection. For example, the interposer 5204 may couple the IC package 5220 (e.g., a die) to a set of BGA conductive contacts of the coupling components 5216 for coupling to the circuit board 5202. In the example illustrated in FIG. 52, the IC package 5220 and the circuit board 5202 are attached to opposing sides of the interposer 5204; in other examples, the IC package 5220 and the circuit board 5202 may be attached to a same side of the interposer 5204. In some examples, three or more components may be interconnected by way of the interposer 5204.

In some examples, the interposer 5204 may be formed as a PCB, including multiple metal layers separated from one another by layers of dielectric material and interconnected by electrically conductive vias. In some examples, the interposer 5204 may be formed of an epoxy resin, a fiberglass-reinforced epoxy resin, an epoxy resin with inorganic fillers, a ceramic material, or a polymer material such as polyimide. In some examples, the interposer 5204 may be formed of alternate rigid or flexible materials that may include the same materials described above for use in a semiconductor substrate, such as silicon, germanium, and other group III-V and group IV materials. The interposer 5204 may include metal interconnects 5208 and vias 5210, including but not limited to through-silicon vias (TSVs) 5206. The interposer 5204 may further include embedded devices 5214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 5204. The package-on-interposer structure 5236 may take the form of any of the package-on-interposer structures known in the art.

The IC device assembly 5200 may include an IC package 5224 coupled to the first face 5240 of the circuit board 5202 by coupling components 5222. The coupling components 5222 may take the form of any of the examples discussed above with reference to the coupling components 5216, and the IC package 5224 may take the form of any of the examples discussed above with reference to the IC package 5220.

The IC device assembly 5200 illustrated in FIG. 52 includes a package-on-package structure 5234 coupled to the second face 5242 of the circuit board 5202 by coupling components 5228. The package-on-package structure 5234 may include a first IC package 5226 and a second IC package 5232 coupled together by coupling components 5230 such that the first IC package 5226 is disposed between the circuit board 5202 and the second IC package 5232. The coupling components 5228, 5230 may take the form of any of the examples of the coupling components 5216 discussed above, and the IC packages 5226, 5232 may take the form of any of the examples of the IC package 5220 discussed above. The package-on-package structure 5234 may be configured in accordance with any of the package-on-package structures known in the art.

FIG. 53 is a block diagram of an example electrical device 5300 that may include one or more of the example IC package 100. For example, any suitable ones of the components of the electrical device 5300 may include one or more of the device assemblies 5200, IC devices 5100, or dies 5002 disclosed herein, and may be arranged in the example IC package 100. A number of components are illustrated in FIG. 53 as included in the electrical device 5300, but any one or more of these components may be omitted or duplicated, as suitable for the application. In some examples, some or all of the components included in the electrical device 5300 may be attached to one or more motherboards. In some examples, some or all of these components are fabricated onto a single system-on-a-chip (SoC) die.

Additionally, in various examples, the electrical device 5300 may not include one or more of the components illustrated in FIG. 53, but the electrical device 5300 may include interface circuitry for coupling to the one or more components. For example, the electrical device 5300 may not include a display 5306, but may include display interface circuitry (e.g., a connector and driver circuitry) to which a display 5306 may be coupled. In another set of examples, the electrical device 5300 may not include an audio input device 5318 (e.g., microphone) or an audio output device 5308 (e.g., a speaker, a headset, earbuds, etc.), but may include audio input or output device interface circuitry (e.g., connectors and supporting circuitry) to which an audio input device 5318 or audio output device 5308 may be coupled.

The electrical device 5300 may include programmable circuitry 5302 (e.g., one or more processing devices). The programmable circuitry 5302 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 5300 may include a memory 5304, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 5304 may include memory that shares a die with the programmable circuitry 5302. This memory may be used as cache memory and may include embedded dynamic random access memory (eDRAM) or spin transfer torque magnetic random access memory (STT-MRAM).

In some examples, the electrical device 5300 may include a communication chip 5312 (e.g., one or more communication chips). For example, the communication chip 5312 may be configured for managing wireless communications for the transfer of data to and from the electrical device 5300. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 5312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 5312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 5312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 5312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 5312 may operate in accordance with other wireless protocols in other examples. The electrical device 5300 may include an antenna 5322 to facilitate wireless communications and/or to receive other wireless communications (such as AM or FM radio transmissions).

In some examples, the communication chip 5312 may manage wired communications, such as electrical, optical, or any other suitable communication protocols (e.g., the Ethernet). As noted above, the communication chip 5312 may include multiple communication chips. For instance, a first communication chip 5312 may be dedicated to shorter-range wireless communications such as Wi-Fi or Bluetooth, and a second communication chip 5312 may be dedicated to longer-range wireless communications such as global positioning system (GPS), EDGE, GPRS, CDMA, WiMAX, LTE, EV-DO, or others. In some examples, a first communication chip 5312 may be dedicated to wireless communications, and a second communication chip 5312 may be dedicated to wired communications.

The electrical device 5300 may include battery/power circuitry 5314. The battery/power circuitry 5314 may include one or more energy storage devices (e.g., batteries or capacitors) and/or circuitry for coupling components of the electrical device 5300 to an energy source separate from the electrical device 5300 (e.g., AC line power).

The electrical device 5300 may include a display 5306 (or corresponding interface circuitry, as discussed above). The display 5306 may include any visual indicators, such as a heads-up display, a computer monitor, a projector, a touchscreen display, a liquid crystal display (LCD), a light-emitting diode display, or a flat panel display.

The electrical device 5300 may include an audio output device 5308 (or corresponding interface circuitry, as discussed above). The audio output device 5308 may include any device that generates an audible indicator, such as speakers, headsets, or earbuds.

The electrical device 5300 may include an audio input device 5318 (or corresponding interface circuitry, as discussed above). The audio input device 5318 may include any device that generates a signal representative of a sound, such as microphones, microphone arrays, or digital instruments (e.g., instruments having a musical instrument digital interface (MIDI) output).

The electrical device 5300 may include GPS circuitry 5316. The GPS circuitry 5316 may be in communication with a satellite-based system and may receive a location of the electrical device 5300, as known in the art.

The electrical device 5300 may include any other output device 5310 (or corresponding interface circuitry, as discussed above). Examples of the other output device 5310 may include an audio codec, a video codec, a printer, a wired or wireless transmitter for providing information to other devices, or an additional storage device.

The electrical device 5300 may include any other input device 5320 (or corresponding interface circuitry, as discussed above). Examples of the other input device 5320 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 5300 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 5300 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that involve package substrates that include substrate cores containing a stack of discrete glass layers or glass cores having different CTEs. The different CTEs define a CTE gradient that reduces stress within package substrates and, specifically, mitigates against seware failures that are known to arise in substrates with a single, solid glass core with a single CTE. As a result, examples disclosed herein improve yield loss in the fabrication of package substrates and also improve the reliability and/or useful life of IC packages relative to known techniques. In some examples disclosed herein also include metal slugs constructed within such stacks of glass cores to provide thermally conductive paths to facilitate heat dissipation that may arise from the higher IO density made possible through the use of glass-based package substrates. Further, in some examples, fine line spacing redistribution layers (e.g., build-up regions) are achieved using the glass cores as a base layer. In some build-up regions outside of the glass substrate core is omitted entirely and the stack of glass layers functions as the redistribution layers for the package substrate.

Further examples and combinations thereof include the following:

Example 1 includes a substrate for an integrated circuit package, the substrate comprising a first glass layer having a first coefficient of thermal expansion (CTE), and a second glass layer having a second CTE, the second CTE different from the first CTE.

Example 2 includes the substrate of example 1, wherein the first and second glass layers are included in a stack of glass layers, the stack of glass layers includes at least one more glass layer, the at least one more glass layer having a third CTE.

Example 3 includes the substrate of example 2, wherein the stack of glass layers defines a core of the substrate.

Example 4 includes the substrate of example 2, wherein the third CTE is higher than the second CTE, and the second CTE is higher than the first CTE, and the second glass layer is between the first glass layer and the at least one more glass layer.

Example 5 includes the substrate of example 2, wherein the third CTE is approximately equal to the first CTE, and the second glass layer is between the first glass layer and the at least one more glass layer.

Example 6 includes the substrate of any one of examples 1-5, further including an adhesive resin between the first glass layer and the second glass layer.

Example 7 includes the substrate of example 6, further including a first through glass via (TGV) through the first glass layer, and a second TGV through the second glass layer, and a conductive material within the adhesive resin, the first TGV electrically coupled to the second TGV through the conductive material.

Example 8 includes the substrate of example 7, wherein the conductive material is a different material from a material of the first TGV.

Example 9 includes the substrate of example 7, wherein the conductive material is a same material as a material of the first TGV.

Example 10 includes the substrate of any one of examples 7-9, further including a buffer layer between the adhesive resin and the first glass layer.

Example 11 includes the substrate of any one of examples 1-10, further including a liner between opposing surfaces of the first glass layer, the liner to surround at least a portion of the first TGV.

Example 12 includes the substrate of example 11, wherein the liner extends less than a full length of the TGV.

Example 13 includes the substrate of any one of examples 11 or 12, wherein the liner extends along the opposing surfaces of the first glass layer.

Example 14 includes the substrate of any one of examples 1-13, further including a metal slug in the first glass layer.

Example 15 includes an integrated circuit (IC) package comprising a semiconductor die, and a stack of multiple glass layers, different ones of the glass layers having different compositions.

Example 16 includes the IC package of example 15, wherein the different compositions are associated with different coefficients of thermal expansion (CTEs), and the different CTEs of the different ones of the glass layers define a symmetrical CTE gradient.

Example 17 includes the IC package of example 16, wherein a lowest CTE value in the symmetrical CTE gradient is closer to a middle of the stack of multiple glass layers than a highest CTE value in the symmetrical CTE gradient.

Example 18 includes the IC package of any one of examples 15-17, further including a metal slug within the stack of multiple glass layers, the metal slug defining a thermally conductive path from an interior of the stack of multiple glass layers to an exterior surface of the IC package.

Example 19 includes an apparatus comprising a semiconductor chip, and a package substrate, the semiconductor chip mounted to the package substrate, the package substrate including first and second glass sheets, the first glass sheet having a different coefficient of thermal expansion (CTE) from the second glass sheet.

Example 20 includes the apparatus of example 19, further including an integrated heat spreader, the package substrate including a metal slug within the glass sheets, the metal slug thermally coupled to the integrated heat spreader.

Example 21 includes a package substrate comprising a first glass layer including a first through glass via extending therethrough, the first glass layer having a first coefficient of thermal expansion (CTE), and a second glass layer including a second through glass via extending therethrough, the second glass layer having a second CTE different from the first CTE, the first through glass via electrically coupled to the second through glass via.

Example 22 includes the package substrate of example 21, further including a fine line spacing build-up region adjacent to the first glass layer.

Example 23 includes the package substrate of example 22, further including a solder resist layer defining an outer surface of the package substrate, the fine line spacing build-up region to span a distance between the first glass layer and the solder resist layer.

Example 24 includes the package substrate of any one of examples 22 or 23, wherein the fine line spacing build-up region includes a plurality of thin film dielectric layers, ones of the thin film dielectric layers having a thickness less than 10 μm.

Example 25 includes the package substrate of any one of examples 21-24, further including a redistribution layer defined by metal within a dielectric material between the first and second glass layers.

Example 26 includes the package substrate of example 21, wherein the first and second glass layers are included in a stack of glass layers, the stack of glass layers including at least one other glass layer.

Example 27 includes the package substrate of example 26, wherein the stack of glass layers spans a distance between solder resist layers on outer surfaces of the package substrate.

Example 28 includes the package substrate of any one of examples 21-27, wherein there is no organic-based build-up region between the first glass layer and an outer surface of the package substrate.

Example 29 includes the package substrate of any one of examples 21-28, wherein the first glass layer defines an outer surface of the package substrate.

Example 30 includes the package substrate of any one of examples 21-29, wherein the first glass layer directly abuts the second glass layer.

Example 31 includes the package substrate of example 30, wherein the second glass layer includes a metal trace defined by a trench extending along an interface between the first and second glass layers.

Example 32 includes the package substrate of example 31, wherein the first through glass via is electrically coupled to the second through glass by the metal trace.

Example 33 includes an integrated circuit (IC) package comprising a semiconductor die, and a package substrate including a stack of glass sheets, different sheets in the stack of glass sheets having different coefficients of thermal expansion (CTE) to define a CTE gradient across the stack.

Example 34 includes the IC package of example 33, wherein the semiconductor die is a first semiconductor die, and the package substrate includes a build-up region between the stack of glass sheets and the first semiconductor die, the build-up region to provide die-to-die interconnects between the first semiconductor die and a second semiconductor die with a line spacing less than or equal to 2 μm/2 μm.

Example 35 includes the IC package of example 34, wherein the package substrate does not include a silicon-based interconnect bridge embedded therein to provide the die-to-die interconnects.

Example 36 includes the IC package of any one of examples 33-35, wherein the package substrate does not include a build-up region on at least one side of the stack of glass sheets.

Example 37 includes the IC package of any one of examples 33-36, wherein the different ones of the sheets in the stack of glass sheets are fusion bonded together.

Example 38 includes an apparatus comprising a semiconductor chip, and a substrate on which the semiconductor chip is mounted, the substrate including a substrate core, the substrate core including a layer of glass and a second layer of glass, the first layer of glass closer to the semiconductor chip than the second layer of glass is to the semiconductor chip, the first layer of glass having different material properties from the second layer of glass.

Example 39 includes the substrate of example 38, wherein the first layer of glass is in contact with the second layer of glass.

Example 40 includes the substrate of any one of examples 38 or 39, further including a conductive trace extending parallel to and between the first and second layers of glass.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A substrate for an integrated circuit package, the substrate comprising:
a first glass layer having a first coefficient of thermal expansion (CTE); and
a second glass layer having a second CTE, the second CTE different from the first CTE.

2. The substrate of claim 1, wherein the first and second glass layers are included in a stack of glass layers, the stack of glass layers includes at least one more glass layer, the at least one more glass layer having a third CTE.

3. The substrate of claim 2, wherein the stack of glass layers defines a core of the substrate.

4. The substrate of claim 2, wherein the third CTE is higher than the second CTE, and the second CTE is higher than the first CTE, and the second glass layer is between the first glass layer and the at least one more glass layer.

5. The substrate of claim 2, wherein the third CTE is approximately equal to the first CTE, and the second glass layer is between the first glass layer and the at least one more glass layer.

6. The substrate of claim 1, further including an adhesive resin between the first glass layer and the second glass layer.

7. The substrate of claim 6, further including:
a first through glass via (TGV) through the first glass layer; and
a second TGV through the second glass layer; and
a conductive material within the adhesive resin, the first TGV electrically coupled to the second TGV through the conductive material.

8. The substrate of claim 7, wherein the conductive material is a different material from a material of the first TGV.

9. The substrate of claim 7, wherein the conductive material is a same material as a material of the first TGV.

10. The substrate of claim 7, further including a buffer layer between the adhesive resin and the first glass layer.

11. The substrate of claim 7, further including a liner between opposing surfaces of the first glass layer, the liner to surround at least a portion of the first TGV.

12. The substrate of claim 11, wherein the liner extends less than a full length of the TGV.

13. The substrate of claim 11, wherein the liner extends along the opposing surfaces of the first glass layer.

14. The substrate of claim 1, further including a metal slug in the first glass layer.

15. An integrated circuit (IC) package comprising:
a semiconductor die; and
a stack of multiple glass layers, different ones of the glass layers having different compositions.

16. The IC package of claim 15, wherein the different compositions are associated with different coefficients of thermal expansion (CTEs), and the different CTEs of the different ones of the glass layers define a symmetrical CTE gradient.

17. The IC package of claim 16, wherein a lowest CTE value in the symmetrical CTE gradient is closer to a middle of the stack of multiple glass layers than a highest CTE value in the symmetrical CTE gradient.

18. The IC package of claim 15, further including a metal slug within the stack of multiple glass layers, the metal slug defining a thermally conductive path from an interior of the stack of multiple glass layers to an exterior surface of the IC package.

19. An apparatus comprising:
a semiconductor chip; and
a package substrate, the semiconductor chip mounted to the package substrate, the package substrate including first and second glass sheets, the first glass sheet having a different coefficient of thermal expansion (CTE) from the second glass sheet.

20. The apparatus of claim 19, further including an integrated heat spreader, the package substrate including a metal slug within the glass sheets, the metal slug thermally coupled to the integrated heat spreader.
